(19) United States
(12) Patent Application Publication
(10) Pub. No.: US 2026/0343999 A1
(43) Pub. Date: Oct. 29, 2026

(54) SEMICONDUCTOR APPARATUS AND METHOD FOR MANUFACTURING SEMICONDUCTOR APPARATUS

(71) Applicant: FUJI ELECTRIC CO., LTD., Kanagawa (JP)

(72) Inventors: Motoyoshi KUBOUCHI, Matsumoto-city (JP); Makoto SHIMOSAWA, Matsumoto-city (JP)

(21) Appl. No.: 19/545,014

(22) Filed: Feb. 20, 2026

(30) Foreign Application Priority Data
Mar. 31, 2025 (JP) 2025-057771

(51) Int. Cl. H10D 64/62

(52) U.S. Cl. CPC H10D 64/62

(57) ABSTRACT

Provided is a semiconductor apparatus including: a silicon layer; an interlayer dielectric film made of silicate glass, which includes a contact hole and is provided above the silicon layer; an intervening layer provided above the interlayer dielectric film; a barrier metal layer provided above the intervening layer; a front-surface-side metal layer provided above the barrier metal layer; and a silicide layer provided above the silicon layer in the contact hole. Provided is a method for manufacturing a semiconductor apparatus, the method including: providing an interlayer dielectric film made of silicate glass above a silicon layer; providing an intervening layer above the interlayer dielectric film; providing a barrier metal layer above the intervening layer; providing a silicide layer above the silicon layer in a contact hole provided in the interlayer dielectric film; and providing a front-surface-side metal layer above the barrier metal layer.

### CROSS REFERENCE TO RELATED APPLICATIONS

The contents of the following patent application (s) are incorporated herein by reference: NO. 2025-057771 filed in JP on Mar. 31, 2025.

### BACKGROUND

### 1. Technical Field

The present invention relates to a semiconductor apparatus and a method for manufacturing the semiconductor apparatus.

### 2. RELATED ART

Patent Document 1 describes a semiconductor apparatus including a “first alloy layer”, an “oxide layer”, a “barrier metal layer”, and a “plug layer”.

### RELATED ART DOCUMENTS

### Patent Documents

Patent Document 1: International Publication No. 2024/014401

Patent Document 2: International Publication No. 2024/014402

Patent Document 3: International Publication No. 2024/171683

Patent Document 4: Japanese Patent No. 7420270

Patent Document 5: Japanese Patent Application Publication No. 2021-168418

Patent Document 6: Japanese Patent Application Publication No. 2024-084054

Patent Document 7: Japanese Patent Application Publication No. 2024-101464

### BRIEF DESCRIPTION OF THE DRAWINGS

FIG. 1A shows an example of a top view of a semiconductor apparatus 100.

FIG. 1B shows an example of a cross section a-a’ in FIG. 1A.

FIG. 1C shows an example of a cross section b-b’ in FIG. 1A.

FIG. 2A shows a top view of a modified example of the semiconductor apparatus 100.

FIG. 2B shows a top view of a modified example of the semiconductor apparatus 100.

FIG. 2C shows an example of a cross section c-c’ in FIG. 2B.

FIG. 2D shows an example of a cross section d-d’ in FIG. 2B.

FIG. 3A is an enlarged view of a cross section of the semiconductor apparatus 100.

FIG. 3B is an enlarged view of a cross section of the semiconductor apparatus 100.

FIG. 4A is an enlarged view of a cross section of the semiconductor apparatus 100.

FIG. 4B is an enlarged view of a cross section of the semiconductor apparatus 100.

FIG. 5A is an enlarged view of a cross section of the semiconductor apparatus 100.

FIG. 5B is an enlarged view of a cross section of the semiconductor apparatus 100.

FIG. 6 shows an example of a cross section e-e’ in FIGS. 1A or 2B .

FIG. 7 shows an example of a cross section f-f’ in FIGS. 1A or 2B .

FIG. 8 shows an example of a top view of the semiconductor apparatus 100 including a temperature sensing unit 180.

FIG. 9 is an example of an enlarged view of a cross section in the temperature sensing unit 180.

FIG. 10A shows an example of a cross section g-g’ in FIG. 8.

FIG. 10B shows an example of the cross section g-g’ in FIG. 8.

FIG. 10C shows an example of the cross section g-g’ in FIG. 8.

FIG. 11A is a flowchart showing an example of a process of manufacturing the semiconductor apparatus 100.

FIG. 11B shows an example of a process of manufacturing the semiconductor apparatus 100.

FIG. 12A is a flowchart showing an example of a process of manufacturing the semiconductor apparatus 100.

FIG. 12B shows an example of a process of manufacturing the semiconductor apparatus 100.

### DESCRIPTION OF EXEMPLARY EMBODIMENTS

Hereinafter, the present invention will be described through embodiments of the invention, but the following embodiments do not limit the invention according to the claims. In addition, not all combinations of features described in the embodiments are essential to a solution of the invention.

In the present specification, one side in a direction parallel to a depth direction of a semiconductor substrate is referred to as “upper” and another side is referred to as “lower”. One surface of two principal surfaces of a substrate, a layer or other member is referred to as an upper surface, and another surface is referred to as a lower surface. “Upper” and “lower” directions are not limited to a direction of gravity, or a direction in which a semiconductor apparatus is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to represent the height direction with respect to the ground. It should be noted that a +Z axis direction and a -Z axis direction are directions opposite to each other. When a Z axis direction is described without describing the signs, it means that the direction is parallel to the +Z axis and the -Z axis.

In the present specification, orthogonal axes parallel to the upper surface and the lower surface of the semiconductor substrate are referred to as the X axis and the Y axis, respectively. In addition, an axis perpendicular to the upper surface and the lower surface of the semiconductor substrate is referred to as the Z axis. In the present specification, the direction of the Z axis may be referred to as a depth direction. In addition, in the present specification, a direction parallel to the upper surface and the lower surface of the semiconductor substrate may be referred to as a horizontal direction, including the X axis and the Y axis.

In the present specification, a description of a P+ type or an N+ type means a higher doping concentration than that of a P type or an N type, and a description of a P- type or an N- type means a lower doping concentration than that of the P type or the N type.

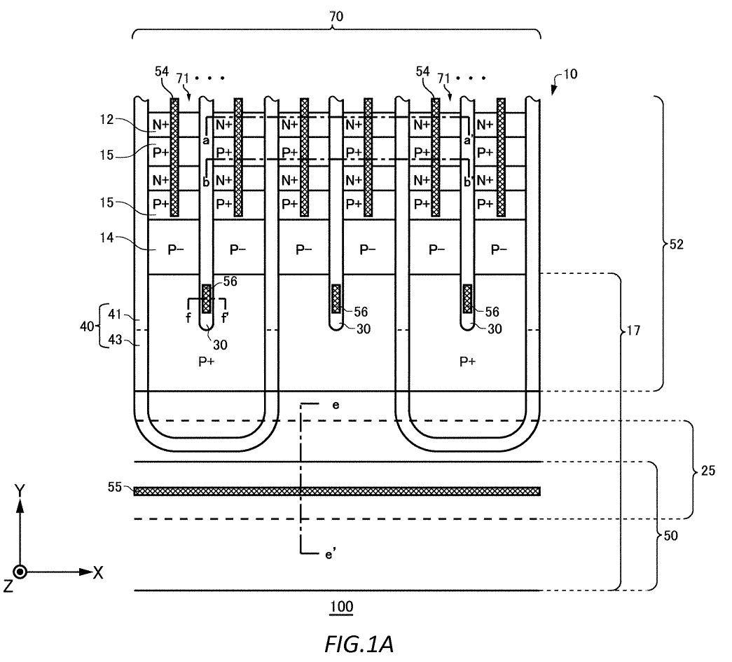

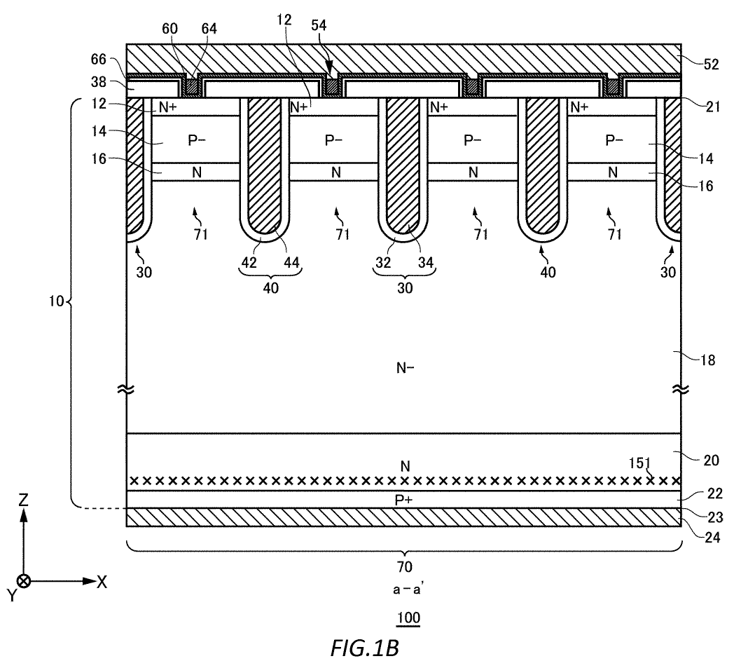

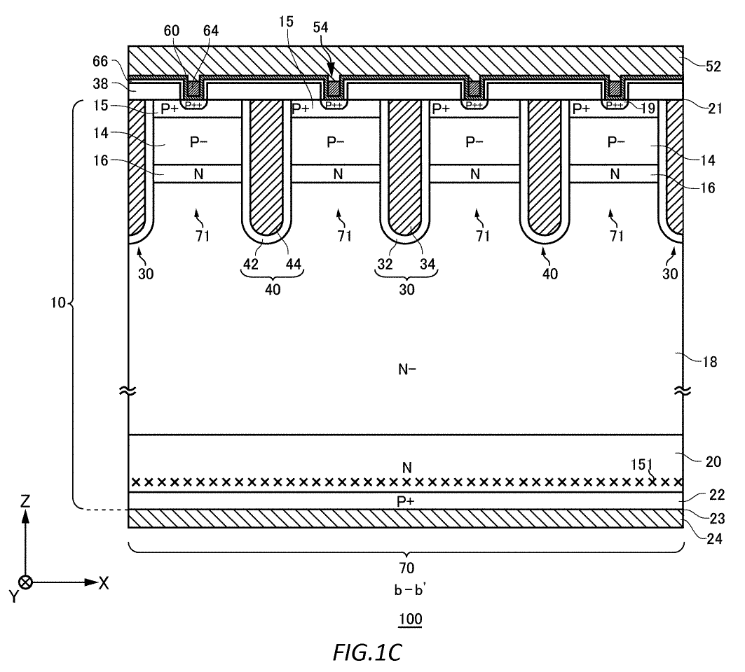

FIG. 1A shows an example of a top view of the semiconductor apparatus 100. The semiconductor apparatus 100 in the present example is a semiconductor chip that includes a transistor portion 70. The semiconductor apparatus 100 is not limited to a transistor as long as it is a semiconductor device in which a semiconductor substrate 10 has a MOS gate structure.

The transistor portion 70 is a region obtained by projecting a collector region 22 provided in a back surface side of the semiconductor substrate 10 onto an upper surface of the semiconductor substrate 10. The collector region 22 will be described later. The transistor portion 70 includes transistors such as IGBTs. In the present example, the transistor portion 70 is an IGBT. It should be noted that the transistor portion 70 may be other transistors such as a MOSFET.

The present figure shows a region around an active portion of the semiconductor apparatus 100 and other regions are omitted. For example, an edge termination structure portion may be provided in a region in a negative side of a Y axis direction in the semiconductor apparatus 100 in the present example. The edge termination structure portion is to alleviate electric field strength in the upper surface side of the semiconductor substrate 10. The edge termination structure portion includes, for example, a guard ring, a field plate, or a RESURF structure, or combinations thereof. It should be noted that although the present example describes the edge in the negative side in the Y axis direction for convenience, the same applies to other edges of the semiconductor apparatus 100.

The semiconductor substrate 10 is a substrate that is formed of a semiconductor material. The semiconductor substrate 10 may be a silicon substrate, may be a silicon carbide substrate, may be a gallium nitride substrate, may be a diamond substrate, or may be other kinds of substrate. The semiconductor substrate 10 in the present example is the silicon substrate. The semiconductor substrate 10 is an example of a silicon layer 110, which will be described later. The silicon layer 110 is an example of a base layer. It should be noted that when simply referred to as a top view in the present specification, it means that the upper surface side of the semiconductor substrate 10 is viewed from above. As will be described later, the semiconductor substrate 10 includes a front surface 21 and a back surface 23.

The semiconductor apparatus 100 in the present example includes, at the front surface 21 of the semiconductor substrate 10, a gate trench portion 40, a dummy trench portion 30, an emitter region 12, a base region 14, a contact region 15 and a well region 17. In addition, the semiconductor apparatus 100 in the present example includes an emitter electrode 52 and a gate metal layer 50 provided above the front surface 21 of the semiconductor substrate 10. The emitter electrode 52 and the gate metal layer 50 are examples of a front-surface-side metal layer 53, which will be described later. The gate trench portion 40 is an example of the MOS gate structure provided in the semiconductor apparatus 100. It should be noted that although the semiconductor apparatus 100 in the present example is a transistor including the MOS gate structure, the semiconductor apparatus 100 may be a diode including the MOS gate structure.

The emitter electrode 52 is provided above the gate trench portion 40, the dummy trench portion 30, the emitter region 12, the base region 14, the contact region 15, and the well region 17. In addition, the gate metal layer 50 is provided above a connection section 25 and the well region 17.

The emitter electrode 52 and the gate metal layer 50 are formed of a material including a metal. At least a portion of the emitter electrode 52 may be formed of metal such as aluminum (Al) or of a metal alloy such as an aluminum-silicon alloy (AlSi) or an aluminum-silicon-copper alloy (AlSiCu). At least a portion of the gate metal layer 50 may be formed of metal such as aluminum (Al) or a metal alloy such as an aluminum-silicon alloy (AlSi) and an aluminum-silicon-copper alloy (AlSiCu). The emitter electrode 52 and the gate metal layer 50 are provided separately from each other.

The emitter electrode 52 and the gate metal layer 50 are provided above the semiconductor substrate 10 to sandwich an interlayer dielectric film 38. The interlayer dielectric film 38 is omitted in FIG. 1A. A barrier metal layer 60 and an intervening layer 66, which will be described later, are provided between the emitter electrode 52 and the gate metal layer 50, and the interlayer dielectric film 38. The barrier metal layer 60 and the intervening layer 66 are omitted in FIG. 1A. A contact hole 54, a contact hole 55, and a contact hole 56 are provided so as to penetrate through the interlayer dielectric film 38.

The contact hole 55 electrically connects the gate metal layer 50 and the gate conductive portion in the transistor portion 70 via the connection section 25. A plug layer formed of tungsten or the like may be formed within the contact hole 55. The plug layer will be described later.

The contact hole 56 connects the emitter electrode 52 with a dummy conductive portion within the dummy trench portion 30. A plug layer formed of tungsten or the like may be formed within the contact hole 56.

The connection section 25 is connected to the front-surface-side metal layer 53 such as the emitter electrode 52 or the gate metal layer 50. In an example, the connection section 25 is provided between the gate metal layer 50 and the gate conductive portion. The connection section 25 in the present example may be provided extending in an X axis direction and electrically connected to the gate conductive portion. The connection section 25 may also be provided between the emitter electrode 52 and the dummy conductive portion. In the present example, the connection section 25 is not provided between the emitter electrode 52 and the dummy conductive portion. The connection section 25 is made of an electrically conductive material such as polysilicon doped with an impurity. The connection section 25 in the present example is polysilicon doped with an N type impurity (N+). The connection section 25 is provided above the front surface 21 of the semiconductor substrate 10 with a dielectric film such as an oxide film, or the like, interposed therebetween.

The gate trench portions 40 are an example of a plurality of trench portions extending in a predetermined extending direction on the front surface 21 side of the semiconductor substrate 10. The gate trench portions 40 are arrayed at predetermined intervals along a predetermined array direction (the X axis direction in the present example). The gate trench portion 40 may have two extending portions 41 extending along the extending direction (the Y axis direction in the present example) which is parallel to the front surface 21 of the semiconductor substrate 10 and is perpendicular to the array direction, and a connection portion 43 which connects the two extending portions 41.

At least a part of a connection portion 43 is preferably formed in a curved shape. By connecting end portions of the two extending portions 41 of the gate trench portions 40, electric field strength at the end portions of the extending portions 41 can be alleviated. In the connection portion 43 of the gate trench portion 40, the gate metal layer 50 may be electrically connected to the gate conductive portion via the connection section 25.

Dummy trench portions 30 are an example of the plurality of trench portions extending in the predetermined extending direction on the front surface 21 side of the semiconductor substrate 10. The dummy trench portion 30 is a trench portion that is electrically connected to the emitter electrode 52. Similarly to the gate trench portions 40, the dummy trench portions 30 are arrayed at a predetermined interval along a predetermined array direction (the X axis direction in the present example). The dummy trench portion 30 in the present example has an I shape at the front surface 21 of the semiconductor substrate 10, but may have a U shape at the front surface 21 of the semiconductor substrate 10 similarly to the gate trench portion 40. That is, the dummy trench portion 30 may include two extending portions which extend along the extending direction and a connection portion which connects the two extending portions.

The transistor portion 70 in the present example has a repetitive array structure of two gate trench portions 40 and two dummy trench portions 30. That is, the transistor portion 70 in the present example includes the gate trench portions 40 and the dummy trench portions 30 at a ratio of 1:1. For example, the transistor portion 70 includes one dummy trench portion 30 between the two extending portions 41.

It should be noted, however, that the ratio of the gate trench portion 40 and the dummy trench portion 30 is not limited to the present example. The ratio of the gate trench portions 40 may be greater than the ratio of the dummy trench portions 30, or the ratio of the dummy trench portions 30 may be greater than the ratio of the gate trench portions 40. The ratio of the gate trench portions 40 and the dummy trench portions 30 may be 2:3 or may be 2:4. In addition, the transistor portion 70 may not have the dummy trench portions 30 with all the trench portions being the gate trench portions 40.

The well region 17 is a region of a second conductivity type which is provided in a front surface 21 side of the semiconductor substrate 10 relative to a drift region 18 which will be described later. The well region 17 is an example of a well region provided in a peripheral side of the active portion 120. The active portion 120 will be described later. The well region 17 is, for example, of the P+ type. The well region 17 is formed within a predetermined range from an end portion of the active region in a side in which the gate metal layer 50 is provided. A diffusion depth of the well region 17 may be deeper than depths of the gate trench portion 40 and the dummy trench portion 30. Portions of the gate trench portion 40 and the dummy trench portion 30 on the gate metal layer 50 side are formed in the well region 17. The bottoms at the end of the extending direction of the gate trench portion 40 and the dummy trench portion 30 may be covered with the well region 17.

The contact hole 54 is formed above each region of the emitter region 12 and the contact region 15 in the transistor portion 70. The contact hole 54 is not provided above the well region 17 provided at both ends of the Y axis direction. Thus, the interlayer dielectric film includes one or more contact holes 54 formed therein. One or more contact holes 54 may be provided so as to extend in the extending direction.

A mesa portion 71 is a mesa portion provided in direct contact with the trench portion in a plane parallel to the front surface 21 of the semiconductor substrate 10. The mesa portion is a portion of the semiconductor substrate 10 interposed between two trench portions adjacent to each other, and may be a portion ranging from the front surface 21 of the semiconductor substrate 10 to the depth of the deepest bottom of each trench portion. The extending portions of each trench portion may be regarded as one trench portion. That is, the region sandwiched between two extending portions may be set to be a mesa portion.

The mesa portion 71 is provided in direct contact with at least one of the dummy trench portion 30 or the gate trench portion 40 in the transistor portion 70. The mesa portion 71 includes the well region 17, the emitter region 12, the base region 14, and the contact region 15 at the front surface 21 of the semiconductor substrate 10. The mesa portion 71 includes the emitter regions 12 and the contact regions 15 alternately provided in the extending direction.

The base region 14 is a region of the second conductivity type provided on the front surface 21 side of the semiconductor substrate 10. The base region 14 is, for example, of the P- type. The base region 14 may be provided at both end portions of the mesa portion 71 in the Y axis direction, at the front surface 21 of the semiconductor substrate 10. It should be noted that FIG. 1A shows only one end portion of the base region 14 in the Y axis direction.

The emitter region 12 is a region of a first conductivity type having a higher doping concentration than the drift region 18. The emitter region 12 in the present example is, for example, of the N+ type. Examples of a dopant of the emitter region 12 include arsenic (As). The emitter region 12 is provided in contact with the gate trench portion 40 at the front surface 21 in the mesa portion 71. The emitter region 12 may be provided so as to extend in the X axis direction from one of two trench portions sandwiching the mesa portion 71 to another of the two trench portions. The emitter region 12 is provided also below the contact hole 54.

In addition, the emitter region 12 may or may not be in contact with the dummy trench portion 30. The emitter region 12 in the present example is in contact with the dummy trench portion 30.

The contact region 15 is a region of the second conductivity type, which is provided above the base region 14 and has a higher doping concentration than the base region 14. The contact region 15 in the present example is, for example, of the P+ type. The contact region 15 in the present example is provided at the front surface 21 of the mesa portion 71. The contact region 15 may be provided in the X axis direction from one of two trench portions sandwiching the mesa portion 71 to another of the two trench portions. The contact region 15 may or may not be in contact with the gate trench portion 40 or the dummy trench portion 30. The contact region 15 in the present example is in contact with the dummy trench portion 30 and the gate trench portion 40. The contact region 15 is provided also below the contact hole 54.

FIG. 1B shows an example of the cross section a-a’ in FIG. 1A. The cross section a-a’ is an XZ plane passing through the emitter region 12 in the transistor portion 70. The semiconductor apparatus 100 in the present example includes, in the cross section a-a’, the semiconductor substrate 10, the interlayer dielectric film 38, the intervening layer 66, the barrier metal layer 60, a plug layer 64, the emitter electrode 52, and a collector electrode 24. The collector electrode 24 is an example of a back-surface-side metal layer provided in contact with the back surface 23 of the semiconductor substrate 10. The emitter electrode 52 is formed above the semiconductor substrate 10 and the interlayer dielectric film 38.

The drift region 18 is a region of the first conductivity type which is provided in the semiconductor substrate 10. The drift region 18 in the present example is, for example, of the N- type. The drift region 18 may be a region which has remained without other doping regions formed in the semiconductor substrate 10. That is, the doping concentration of the drift region 18 may be the doping concentration of the semiconductor substrate 10.

A buffer region 20 is a region of the first conductivity type which is provided on a back surface 23 side of the semiconductor substrate 10 relative to the drift region 18. The buffer region 20 in the present example is, for example, of the N type. The doping concentration in the buffer region 20 is higher than the doping concentration in the drift region 18. The buffer region 20 may function as a field stop layer which prevents a depletion layer extending from the lower surface side of the base regions 14 from reaching the collector region 22 of the second conductivity type. It should be noted that the buffer region 20 may be omitted.

The collector region 22 is provided below the buffer region 20 in the transistor portion 70. The collector region 22 has the second conductivity type. The collector region 22 in the present example is, for example, of the P+ type.

The collector electrode 24 is formed at the back surface 23 of the semiconductor substrate 10. The collector electrode 24 is formed of a conductive material such as metal. A material of the collector electrode 24 may be the same as or different from a material of the emitter electrode 52.

The base region 14 is a region of the second conductivity type which is provided above the drift region 18. The base region 14 is provided in contact with the gate trench portion 40. The base region 14 may be provided in contact with the dummy trench portion 30.

The emitter region 12 is provided above the base region 14. The emitter region 12 is provided between the base region 14 and the front surface 21. The emitter region 12 is provided in contact with the gate trench portion 40. The emitter region 12 may or may not be in contact with the dummy trench portion 30.

An accumulation region 16 is a region of the first conductivity type which is provided on the front surface 21 side of the semiconductor substrate 10 relative to the drift region 18. The accumulation region 16 in the present example is, for example, of N type. It should be noted, however, that the accumulation region 16 may not be provided.

The accumulation region 16 is provided in contact with the gate trench portion 40. The accumulation region 16 may be or may not be in contact with the dummy trench portion 30. The doping concentration of the accumulation region 16 is higher than the doping concentration of the drift region 18. An ion implantation dose amount of the accumulation region 16 may be 1.0E + 12 cm⁻² or more and 1.0E + 13 cm⁻² or less. In addition, the ion implantation dose amount of the accumulation region 16 may be 3.0E + 12 cm⁻² or more and 6.0E + 12 cm⁻² or less. By providing the accumulation region 16, the carrier injection enhancement effect (IE effect) can be increased, and an ON voltage of the transistor portion 70 can be reduced.

One or more gate trench portions 40 and one or more dummy trench portions 30 are provided at the front surface 21. Each trench portion is provided from the front surface 21 to the drift region 18. In a region provided with at least any of the emitter region 12, the base region 14, or the accumulation region 16, each trench portion also penetrates these regions to reach the drift region 18. The configuration of the trench portion penetrating the doping region is not limited to the one manufactured in the order of formation of the doping region and then forming the trench portion. The configuration of the trench portion penetrating the doping region also includes a configuration of the doping region being formed between the trench portions after forming the trench portions.

The gate trench portion 40 has a gate trench, a gate dielectric film 42, and a gate conductive portion 44 which are formed at the front surface 21. The gate dielectric film 42 is formed to cover an inner wall of the gate trench. The gate dielectric film 42 may be formed by oxidizing or nitriding a semiconductor on the inner wall of the gate trench. In another example, the gate dielectric film 42 may be formed by depositing a dielectric substance such as an oxide film. The gate conductive portion 44 is formed inward of the gate dielectric film 42 within the gate trench. The gate dielectric film 42 insulates the gate conductive portion 44 from the semiconductor substrate 10. The gate conductive portion 44 is formed of a conductive material such as polysilicon. The gate conductive portion 44 in the present example is, for example, of the N+ type. The gate trench portion 40 is covered with the interlayer dielectric film 38 at the front surface 21.

The gate conductive portion 44 includes a region opposing the adjacent base region 14 in the mesa portion 71 side by sandwiching the gate dielectric film 42 in a depth direction of the semiconductor substrate 10. When a predefined voltage is applied to the gate conductive portion 44, a channel is formed to a surface layer being at a boundary surface of the base region 14 and in contact with the gate trench, due to an electron inversion layer.

The dummy trench portion 30 may have the same structure as the gate trench portion 40. The dummy trench portion 30 has a dummy trench, a dummy dielectric film 32, and a dummy conductive portion 34 which are formed on the front surface 21 side. The dummy dielectric film 32 is formed covering the inner walls of the dummy trench. The dummy conductive portion 34 is formed within the dummy trench, and is formed inward of the dummy dielectric film 32. The dummy dielectric film 32 insulates the dummy conductive portion 34 from the semiconductor substrate 10. The dummy trench portion 30 may be covered with the interlayer dielectric film 38 at the front surface 21.

The interlayer dielectric film 38 is provided above the semiconductor substrate 10. The interlayer dielectric film 38 in the present example is provided in contact with the front surface 21. The emitter electrode 52 is provided above the interlayer dielectric film 38. The interlayer dielectric film 38 is provided with one or more contact holes 54 to electrically connect the emitter electrode 52 and the semiconductor substrate 10. In the present example, a bottom surface of the contact hole 54 is not positioned below the front surface 21 of the semiconductor substrate 10 provided below the interlayer dielectric film 38, but in another example, the bottom surface of the contact hole 54 may be positioned below the front surface 21 of the semiconductor substrate 10 provided below the interlayer dielectric film 38. Similarly, the contact hole 55 and the contact hole 56 may also be provided so as to penetrate the interlayer dielectric film 38, and bottom surfaces of the contact hole 55 and the contact hole 56 may be positioned below upper surfaces of the connection section 25 and the dummy conductive portion 34 provided below the interlayer dielectric film 38. A film thickness of the interlayer dielectric film 38 is, for example, 1.0 μm, but is not limited thereto.

The interlayer dielectric film 38 may be a silicon oxide film. The interlayer dielectric film 38 may be a BPSG (Boro-phospho Silicate Glass) film, may be a BSG (borosilicate glass) film, or may be a PSG (Phosphosilicate glass) film. The interlayer dielectric film 38 may include a high-temperature silicon oxide (HTO: High Temperature Oxide) film, or may include a low-temperature silicon oxide (LTO: Low Temperature Oxide) film. The configuration of the interlayer dielectric film 38 will be described in detail later.

The intervening layer 66 is provided above the interlayer dielectric film 38. The intervening layer 66 may be provided at a sidewall of the contact hole 54. It should be noted, however, that the intervening layer 66 may be provided only above the interlayer dielectric film 38. The intervening layer 66 will be described in greater detail later.

The barrier metal layer 60 is provided above the intervening layer 66. The barrier metal layer 60 may include a predetermined electrically conductive metal. The barrier metal layer 60 may be provided at the sidewall of the contact hole 54. The barrier metal layer 60 will be described in greater detail later.

The plug layer 64 is provided inward of the barrier metal layer 60 within the contact hole 54. The plug layer 64 is made of an electrically conductive material that fills the interior of the contact hole 54. The plug layer 64 may be made of a material different from that of the emitter electrode 52. For example, a material of the plug layer 64 is tungsten.

A back-surface-side lifetime control region 151 may be provided in the transistor portion 70. It should be noted, however, that the back-surface-side lifetime control region 151 may be omitted. The back-surface-side lifetime control region 151 is a region where a lifetime killer has intentionally been formed by implanting an impurity within the semiconductor substrate 10, or the like. In an example, the back-surface-side lifetime control region 151 is formed by implanting helium into the semiconductor substrate 10. The back-surface-side lifetime control region 151 may also be formed by implanting protons. By providing the back-surface-side lifetime control region 151, a turn-off time can be reduced, and by suppressing a tail current, losses during switching can be reduced.

The lifetime killer is a recombination center of carriers. The lifetime killer may be a lattice defect. For example, the lifetime killer may be a vacancy, a divacancy, a complex defect of these with elements configuring the semiconductor substrate 10, or dislocation. In addition, the lifetime killer may be a noble gas element such as helium and neon, a metal element such as platinum, or the like. An electron beam or a proton may be used for forming the lattice defect.

A lifetime killer concentration is a concentration at the recombination center of carriers. The lifetime killer concentration may be a concentration of the lattice defect. For example, the lifetime killer concentration may be a vacancy concentration of a vacancy, a divacancy, or the like, may be a complex defect concentration of these vacancies with elements configuring the semiconductor substrate 10, or may be a dislocation concentration. In addition, the lifetime killer concentration may be a chemical concentration of the noble gas element such as helium and neon, or may be a chemical concentration of the metal element such as platinum.

The back-surface-side lifetime control region 151 is provided on the back surface 23 side relative to the center of the semiconductor substrate 10 in the depth direction of the semiconductor substrate 10. The back-surface-side lifetime control region 151 in the present example is provided in the buffer region 20. The back-surface-side lifetime control region 151 in the present example is provided on an entire surface of the semiconductor substrate 10 in the XY plane, and can be formed without using a mask. The back-surface-side lifetime control region 151 may be provided in a part of the semiconductor substrate 10 in the XY plane. An impurity dose amount for forming the back-surface-side lifetime control region 151 may be 0.5E + 10 cm⁻² or more and 1.0E + 14 cm⁻² or less, or may be 5.0E + 10 cm⁻² or more and 1.0E + 13 cm⁻² or less.

The back-surface-side lifetime control region 151 may be formed by implantation from the back surface 23 side. Accordingly, it becomes easy to avoid an effect on the front surface 21 side of the semiconductor apparatus 100. For example, the back-surface-side lifetime control region 151 is formed by irradiating helium or a proton from the back surface 23 side. Here, which of the front surface 21 side and the back surface 23 side the implantation is performed from for forming the back-surface-side lifetime control region 151 can be determined by acquiring a state of the front surface 21 side by an SRP method or measurement of a leakage current.

FIG. 1C shows an example of the cross section b-b’ in FIG. 1A. The cross section b-b’ is the XZ plane passing through the contact region 15 in the mesa portion 71. Similarly to the cross section a-a’, the semiconductor apparatus 100 in the present example includes, in the cross section b-b’, the semiconductor substrate 10, the interlayer dielectric film 38, the intervening layer 66, the barrier metal layer 60, the plug layer 64, the emitter electrode 52, and the collector electrode 24.

The contact region 15 is provided above the base region 14. The contact region 15 is provided between the base region 14 and the front surface 21. The contact region 15 may or may not be in contact with the gate trench portion 40 or the dummy trench portion 30. The contact region 15 in the present example is in contact with the dummy trench portion 30 and the gate trench portion 40.

A plug region 19 is a region of the second conductivity type having a higher doping concentration than the contact region 15. The plug region 19 is, for example, of a P++ type. The plug region 19 in the present example is provided at the front surface 21. The plug region 19 is provided above the contact region 15 in the cross section b-b’. The plug region 19 in the present example is in contact with the contact region 15. The plug region 19 is provided in the mesa portion 71 in the cross section b-b’, but is not provided in the mesa portion 71 in the cross section a-a’. That is, plug regions 19 may be discretely provided in the extending direction at the front surface 21. It should be noted that, in another example, the plug region 19 may not be provided over the entire area above the contact region 15 in the mesa portion 71, and may be provided over a part of the area above the emitter region 12 in the mesa portion 71.

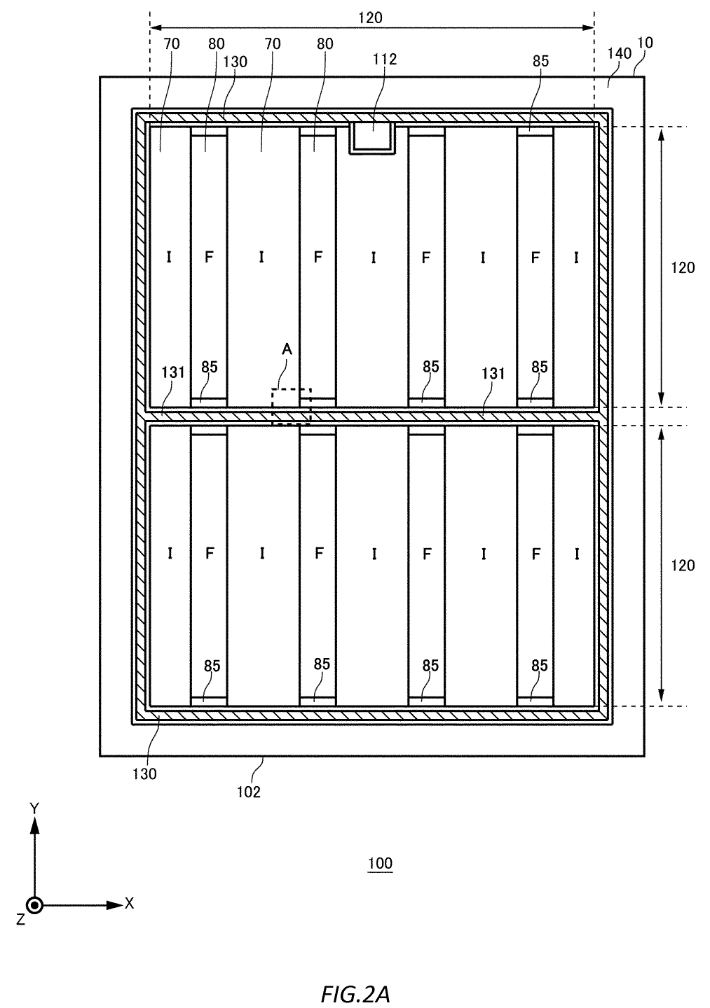

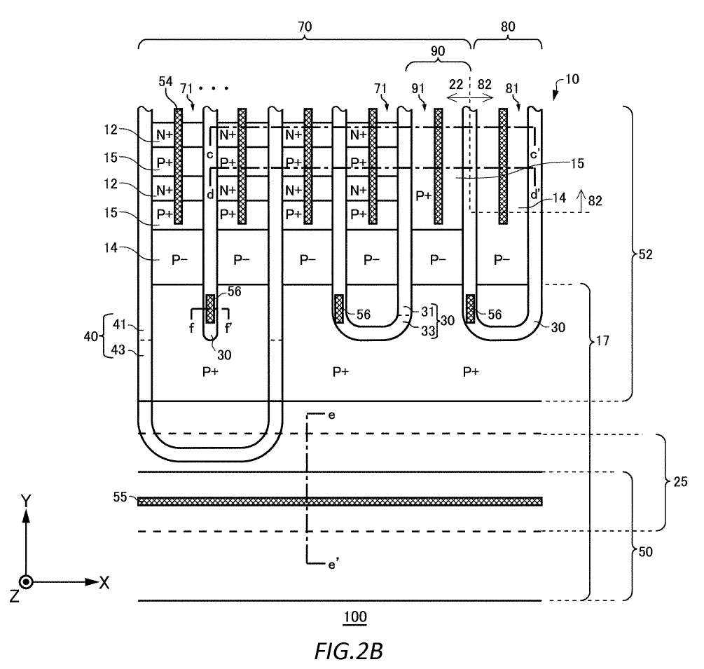

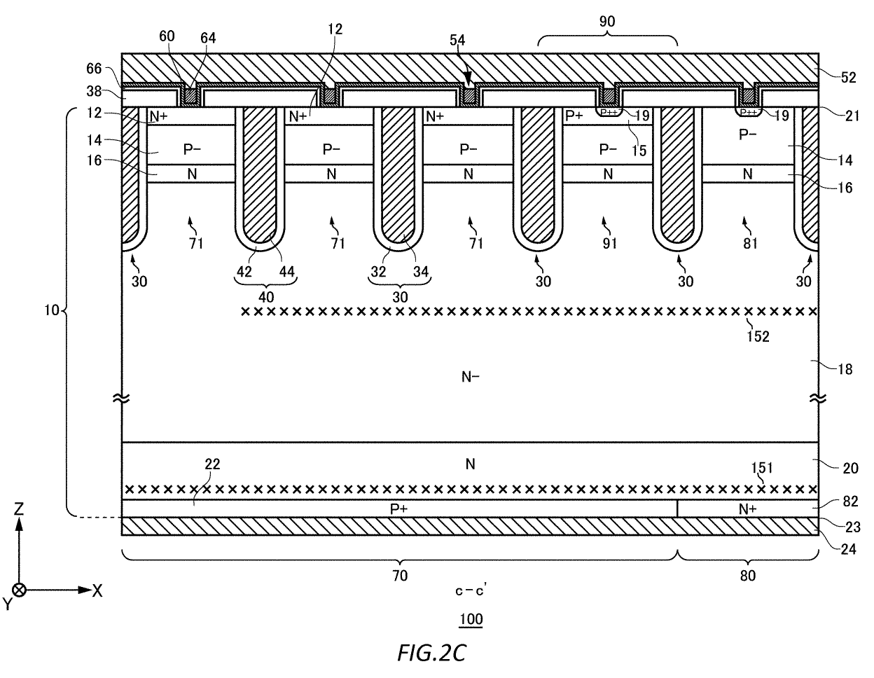

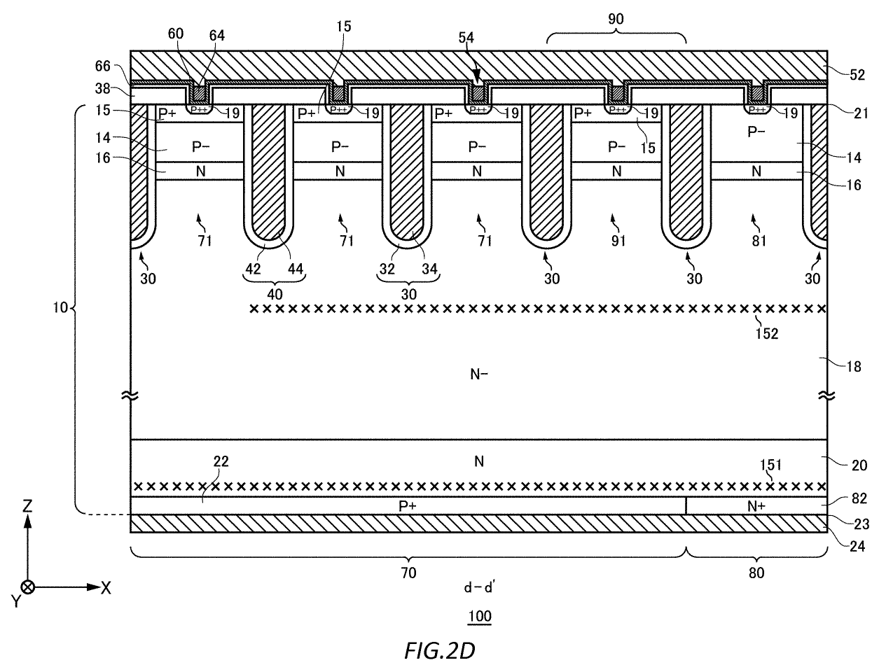

FIG. 2A shows a top view of a modified example of the semiconductor apparatus 100. In the present example, only some members of the semiconductor apparatus 100 are shown and some members are omitted.

The semiconductor substrate 10 has end sides 102 in a top view. The semiconductor substrate 10 in the present example includes two sets of end sides 102 facing each other in a top view. In the present example, the X axis and the Y axis are parallel to any of the end sides 102.

The semiconductor substrate 10 is provided with an active portion 120. The active portion 120 is a region through which a principal current flows in the depth direction between the front surface 21 and the back surface 23 of the semiconductor substrate 10 when the semiconductor apparatus 100 is operated. The emitter electrode 52 is provided above the active portion 120, but is omitted in the present figure.

The active portion 120 is provided with at least one of the transistor portion 70 including a transistor device such as an IGBT or a diode portion 80 including a diode device such as a free wheeling diode (FWD). In the example of FIG. 2A, the transistor portion 70 and the diode portion 80 are alternately arranged along a predefined array direction (the X axis direction in the present example) at the front surface 21 of the semiconductor substrate 10. In another example, the active portion 120 may be provided with only one of the transistor portion 70 and the diode portion 80.

In the present example, a region where the transistor portion 70 is arranged is denoted by a symbol “I”, and a region where the diode portion 80 is arranged is denoted by a symbol “F”. Each of the transistor portions 70 and the diode portions 80 may have a longitudinal length in the extending direction. In other words, the length of each of the transistor portions 70 in the Y axis direction is greater than the width in the X axis direction. Similarly, the length of each of the diode portions 80 in the Y axis direction is greater than the width in the X axis direction. The extending direction of the transistor portion 70 and the diode portion 80, and the longitudinal direction of each trench portion described later may be the same.

The diode portion 80 is a region obtained by projecting a cathode region 82 provided on the back surface 23 side of the semiconductor substrate 10 onto the upper surface of the semiconductor substrate 10. The cathode region 82 will be described later. At the back surface 23 of the semiconductor substrate 10, the collector region 22 of the P+ type may be provided in a region other than the cathode region 82. In the present specification, the diode portion 80 may also include an extension region 85 where the diode portion 80 extends to a gate wiring to be described later in the Y axis direction. At the back surface 23 of the extension region 85, the collector region 22 may be provided.

The semiconductor apparatus 100 may have one or more pads above the semiconductor substrate 10. The semiconductor apparatus 100 in the present example has a gate pad 112. The semiconductor apparatus 100 may have a pad such as an anode pad and a cathode pad. Each pad is arranged in the vicinity of the end side 102. The vicinity of the end side 102 refers to a region between the end side 102 and the emitter electrode 52 in a top view. When the semiconductor apparatus 100 is mounted, each pad may be connected to an external circuit via a wiring such as a wire.

A gate potential is applied to the gate pad 112. The gate pad 112 is electrically connected to the gate conductive portion 44 of the gate trench portion 40 of the active portion 120. The semiconductor apparatus 100 includes a gate wiring that connects the gate pad 112 and the gate trench portion 40. In FIG. 2A, the gate wiring is hatched with diagonal lines.

The gate wiring in the present example has an outer circumferential gate wiring 130 and an inter-active-portion gate wiring 131. The gate wiring may be constituted by either one of the gate metal layer 50 or the connection section 25, or may be constituted by a combination of both as appropriate. The outer circumferential gate wiring 130 and the inter-active-portion gate wiring 131 may have the same configuration or may have a different configuration. The outer circumferential gate wiring 130 is arranged between the active portion 120 and the end side 102 of the semiconductor substrate 10 in a top view. The outer circumferential gate wiring 130 in the present example encloses the active portion 120 in a top view. A region enclosed by the outer circumferential gate wiring 130 in a top view may be the active portion 120. In addition, the outer circumferential gate wiring 130 is connected to the gate pad 112. The outer circumferential gate wiring 130 is arranged above the semiconductor substrate 10. The outer circumferential gate wiring 130 may be composed of the gate metal layer 50 and the connection section 25.

The inter-active-portion gate wiring 131 is provided between a plurality of active portions 120. In FIG. 2A, two active portions 120 are arranged side by side in the Y axis direction. Variations in wiring length from the gate pad 112 can be reduced for each region of the semiconductor substrate 10 by providing the inter-active-portion gate wiring 131 between a plurality of active portions 120 within the semiconductor substrate 10.

The inter-active-portion gate wiring 131 is connected to the gate trench portion of the active portion 120. The inter-active-portion gate wiring 131 is arranged above the semiconductor substrate 10. The inter-active-portion gate wiring 131 in the present example is composed of the gate metal layer 50 and the connection section 25. The gate metal layer 50 may be a metal layer including aluminum or the like.

The inter-active-portion gate wiring 131 may be connected to the outer circumferential gate wiring 130. The inter-active-portion gate wiring 131 in the present example is provided extending in the X axis direction from one outer circumferential gate wiring 130 to another outer circumferential gate wiring 130 substantially at the center of the Y axis direction, so as to cross the active portion 120. When the active portion 120 is divided by the inter-active-portion gate wiring 131, the transistor portion 70 and the diode portion 80 may be alternately arranged in the X axis direction in each divided region.

An edge termination structure portion 140 is provided at the front surface 21 of the semiconductor substrate 10. The edge termination structure portion 140 is provided between the active portion 120 and the end side 102 in a top view. The edge termination structure portion 140 in the present example is arranged between the outer circumferential gate wiring 130 and the end side 102. The edge termination structure portion 140 alleviates electric field strength in the front surface 21 side of the semiconductor substrate 10. The edge termination structure portion 140 may include at least one of a guard ring, a field plate, or a RESURF which is annularly provided so as to enclose the active portion 120.

FIG. 2B shows a top view of the modified example of the semiconductor apparatus 100. The semiconductor apparatus 100 in the present example includes the transistor portion 70 and the diode portion 80. The present figure is an enlarged view of the upper surface of the region A in FIG. 2A.

The semiconductor apparatus 100 in the present example includes the gate trench portion 40, the dummy trench portion 30, the emitter region 12, the base region 14, the contact region 15, and the well region 17 which are provided within the semiconductor substrate 10 on the front surface 21 side. The gate trench portion 40 and the dummy trench portion 30 each are an example of the trench portion.

Similarly to the gate trench portion 40, the dummy trench portion 30 in the present example may have a U shape at the front surface 21 of the semiconductor substrate 10. That is, the dummy trench portion 30 may include two extending portions 31 which extend along the extending direction and a connection portion 33 which connects the two extending portions 31.

The semiconductor apparatus 100 in the present example includes the emitter electrode 52 and the gate metal layer 50 provided above the front surface 21 of the semiconductor substrate 10. The emitter electrode 52 and the gate metal layer 50 are provided separately from each other. The transistor portion 70 in the present example includes a boundary portion 90 which is positioned at a boundary between the transistor portion 70 and the diode portion 80. It should be noted, however, that the semiconductor apparatus 100 may not include the boundary portion 90.

The boundary portion 90 is a region which is provided in the transistor portion 70 and is in direct contact with the diode portion 80. The boundary portion 90 includes the contact region 15 at the front surface 21 of the semiconductor substrate 10. The boundary portion 90 in the present example does not include the emitter region 12. In an example, trench portions in the boundary portion 90 are the dummy trench portions 30. The boundary portion 90 in the present example is arranged such that both ends thereof in the X axis direction become the dummy trench portions 30.

The contact hole 54 is provided above the base region 14 in the diode portion 80. The contact hole 54 is provided above the contact region 15 in the boundary portion 90. No contact holes 54 are provided above the well regions 17 provided at the both ends in the Y axis direction.

A mesa portion 91 is provided in the boundary portion 90. The mesa portion 91 includes the contact region 15 at the front surface 21 of the semiconductor substrate 10. The mesa portion 91 in the present example includes the base region 14 and the well region 17 on a negative side in the Y axis direction.

A mesa portion 81 is provided in a region sandwiched between the dummy trench portions 30 adjacent to each other in the diode portion 80. The mesa portion 81 includes the base region 14 at the front surface 21 of the semiconductor substrate 10. The mesa portion 81 in the present example includes the well region 17 on the negative side in the Y axis direction.

The emitter region 12 is provided in the mesa portion 71, but may not be provided in the mesa portion 81 and the mesa portion 91. The contact region 15 is provided in the mesa portion 71 and the mesa portion 91, but may not be provided in the mesa portion 81.

FIG. 2C shows an example of the cross section c-c’ in FIG. 2B. The cross section c-c’ is the XZ plane passing through the emitter region 12 in the transistor portion 70. The semiconductor apparatus 100 in the present example includes, in the cross section c-c’, the semiconductor substrate 10, the interlayer dielectric film 38, the intervening layer 66, the barrier metal layer 60, the plug layer 64, the emitter electrode 52, and the collector electrode 24. The semiconductor apparatus 100 in the present example includes the back-surface-side lifetime control region 151 and a front-surface-side lifetime control region 152. It should be noted, however, that the semiconductor apparatus 100 may not include one of the back-surface-side lifetime control region 151 or a front-surface-side lifetime control region 152. The semiconductor apparatus 100 in the present example includes the collector region 22 and the cathode region 82 on the back surface 23 side of the buffer region 20.

The contact region 15 is provided above the base region 14 in the mesa portion 91. The contact region 15 is provided in contact with the dummy trench portion 30 in the mesa portion 91. In another cross section, the contact region 15 may be provided at the front surface 21 in the mesa portion 71. The plug region 19 is provided above the contact region 15 in the mesa portion 91, and is provided above the base region 14 in the mesa portion 81.

The accumulation region 16 is provided in the transistor portion 70 and the diode portion 80. The accumulation region 16 in the present example is provided at entire surfaces of the transistor portion 70 and the diode portion 80. It should be noted, however, that the accumulation region 16 may not be provided in the diode portion 80.

The cathode region 82 is provided below the buffer region 20 in the diode portion 80. The boundary between the collector region 22 and the cathode region 82 is a boundary between the transistor portion 70 and the diode portion 80. That is, the collector region 22 is provided below the boundary portion 90 in the present example.

The back-surface-side lifetime control region 151 is provided in both of the transistor portion 70 and the diode portion 80. Accordingly, the semiconductor apparatus 100 in the present example can further reduce switching loss by accelerating recovery in the diode portion 80. The back-surface-side lifetime control region 151 may be formed by a method similar to that of the back-surface-side lifetime control region 151 in another example.

The front-surface-side lifetime control region 152 is provided on the front surface 21 side relative to a center of the semiconductor substrate 10 in the depth direction of the semiconductor substrate 10. The front-surface-side lifetime control region 152 in the present example is provided in the drift region 18. The front-surface-side lifetime control region 152 is provided in both the transistor portion 70 and the diode portion 80. The front-surface-side lifetime control region 152 may be provided in the diode portion 80 and the boundary portion 90 and not be provided in a part of the transistor portion 70. In another example, the front-surface-side lifetime control region 152 may be provided over the entire areas of the transistor portion 70 and the diode portion 80, or over the entire area or a part of either of them, and may also be provided in a region around the active portion 120, such as the edge termination structure portion 140. The front-surface-side lifetime control region 152 can suppress hole implantation from the diode portion 80 and the transistor portion 70, thereby reducing reverse recovery loss.

The front-surface-side lifetime control region 152 may be formed by any method of the methods for forming the back-surface-side lifetime control region 151. An element, a dose amount, and the like for forming the back-surface-side lifetime control region 151 may be the same as or different from those for forming the front-surface-side lifetime control region 152.

The front-surface-side lifetime control region 152 is provided so as to extend from the diode portion 80 to the transistor portion 70. The front-surface-side lifetime control region 152 may be formed through irradiation from the front surface 21 of the semiconductor substrate 10. The front-surface-side lifetime control region 152 may also be formed by irradiation from the back surface 23 side of the semiconductor substrate 10. The front-surface-side lifetime control region 152 in the present example is provided below the gate trench portion 40. Particle beams or the like for forming the front-surface-side lifetime control region 152 may pass through the MOS gate structure of the semiconductor apparatus 100, thereby causing defects at a boundary surface between a gate oxide film and the semiconductor substrate.

The semiconductor apparatus 100 may be a power semiconductor apparatus for performing power control or the like. The semiconductor apparatus 100 in the present example has a vertical semiconductor structure that includes a back-surface-side metal layer on the back surface 23 side of the semiconductor substrate 10. It should be noted, however, that the semiconductor apparatus 100 may have a lateral semiconductor structure that does not include a metal layer on the back surface 23 side.

It should be noted that, in the present example, an RC-IGBT having a trench gate structure is described as an example of the semiconductor apparatus 100. It should be noted, however, that the semiconductor apparatus 100 may be a semiconductor apparatus having a planar gate structure, or may be another semiconductor apparatus such as a diode. The semiconductor apparatus 100 may include an N-channel MOSFET, or may include a P-channel MOSFET.

FIG. 2D shows an example of the cross section d-d’ in FIG. 2B. The cross section d-d’ is the XZ plane passing through the contact region 15 in the mesa portion 71. Similarly to the cross section c-c’, the semiconductor apparatus 100 in the present example includes, in the cross section d-d’, the semiconductor substrate 10, the interlayer dielectric film 38, the intervening layer 66, the barrier metal layer 60, the plug layer 64, the emitter electrode 52, and the collector electrode 24.

The mesa portion 71 includes the base region 14, the contact region 15, the accumulation region 16, and the plug region 19. The mesa portion 91 has the base region 14, the contact region 15, the accumulation region 16, and the plug region 19. Similarly to the cross section c-c’, the mesa portion 81 includes the base region 14, the accumulation region 16, and the plug region 19. The plug region 19 may be continuously provided in the extending direction at the front surface 21 of the mesa portion 81 and the mesa portion 91. In another example, the plug regions 19 may be discretely provided in the extending direction or in the array direction at the front surface 21 of the mesa portion 81 and the mesa portion 91.

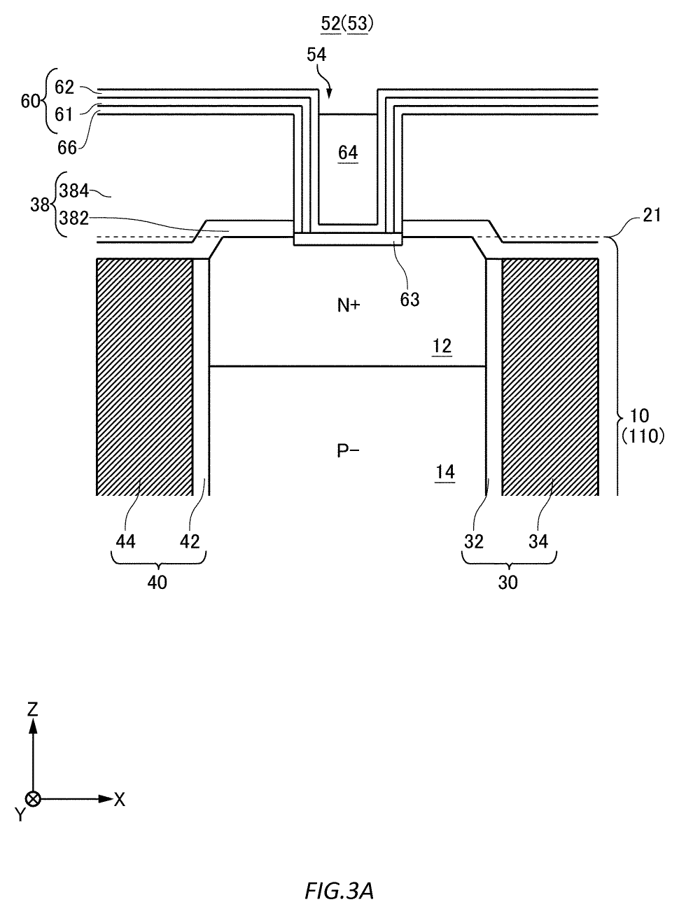

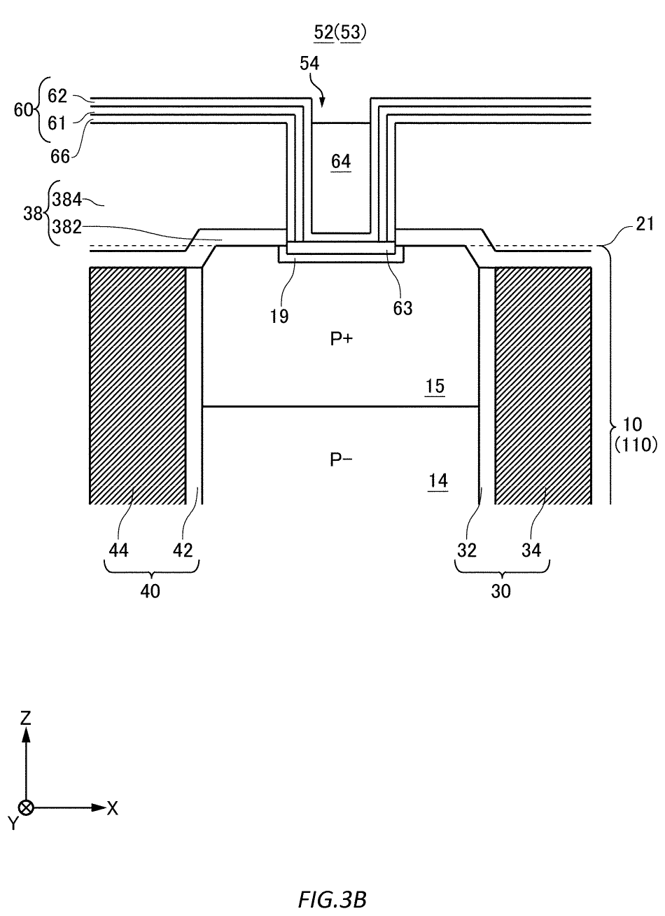

FIG. 3A is an enlarged view of a cross section of the semiconductor apparatus 100. In the present example, the enlarged view of the cross section in the vicinity of the contact hole 54 is shown. The cross section in the present example is the XZ cross section which passes through the emitter region 12 at the front surface 21 of the semiconductor substrate 10. The semiconductor substrate 10 is an example of the silicon layer 110. The emitter electrode 52 is an example of the front-surface-side metal layer 53. The semiconductor apparatus 100 includes the semiconductor substrate 10, the interlayer dielectric film 38, the intervening layer 66, the barrier metal layer 60, the emitter electrode 52, and a silicide layer 63. The semiconductor apparatus 100 may include the plug layer 64.

FIG. 3B is an enlarged view of a cross section of the semiconductor apparatus 100. The cross section in the present example is different from the cross section of FIG. 3A in that it passes through the contact region 15 at the front surface 21. The semiconductor apparatus 100 includes the semiconductor substrate 10, the interlayer dielectric film 38, the intervening layer 66, the barrier metal layer 60, the emitter electrode 52, and the silicide layer 63. The semiconductor apparatus 100 may include the plug region 19 and the plug layer 64. That is, a region below the contact hole 54 of the semiconductor substrate 10, which is an example of the silicon layer 110, may be of the second conductivity type as in the present example, or may be of the first conductivity type as in the example shown in FIG. 3A. A case where the region below the contact hole 54 of the semiconductor substrate 10 is the base region 14 may be similar to a case where it is the contact region 15. With reference to FIGS. 3A and 3B an example will be described in detail below, in which the semiconductor substrate 10, which is an example of the silicon layer 110, and the emitter electrode 52, which is an example of the front-surface-side metal layer 53, are connected through the contact hole 54.

It should be noted that, in the present specification, the contact hole 54 may be used to describe the structure in the vicinity of the contact hole, but similar structures may also be applied to other contact holes such as the contact hole 55 and the contact hole 56. That is, the intervening layer 66, the barrier metal layer 60, the silicide layer 63, the plug layer 64, and the plug region 19 may be provided in other contact holes such as the contact hole 55 and the contact hole 56. Similarly, the intervening layer 66, the barrier metal layer 60, the silicide layer 63, the plug layer 64, and the plug region 19 may be provided in a contact hole 58, which will be described later.

The interlayer dielectric film 38 includes the contact hole 54, and is provided above the silicon layer 110. The interlayer dielectric film 38 in the present example is provided above the semiconductor substrate 10, which is an example of the silicon layer 110. The interlayer dielectric film 38 contains silicate glass. The interlayer dielectric film 38 may include a BPSG film, may include a BSG film, or may include a PSG film.

The interlayer dielectric film 38 may include a first insulating layer 382 and a second insulating layer 384. The first insulating layer 382 may be provided above the silicon layer 110. The first insulating layer 382 in the present example is provided above the semiconductor substrate 10, which is an example of the silicon layer 110. The second insulating layer 384 may be provided above the first insulating layer 382.

The first insulating layer 382 is, for example, a silicon oxide film. The first insulating layer 382 may be an HTO film, or may be an LTO film. In another example, it may be formed through thermal oxidation of the semiconductor substrate 10, the gate conductive portion 44, the dummy conductive portion 34, or the like. The second insulating layer 384 is, for example, a silicate glass. The second insulating layer 384 may be a BPSG film, may be a BSG film, or may be a PSG film.

The second insulating layer 384 may have a higher fluorine concentration or boron concentration than the first insulating layer 382. For example, fluoride ions may be implanted into the bottom of the contact hole 54 in order to form the plug region 19. For example, the fluoride ions are boron fluoride ions (e.g. BF₂ ⁺). In this case, fluoride ions irradiated from above the semiconductor substrate 10 may also be implanted into the second insulating layer 384, and a fluorine concentration in the second insulating layer 384 may be higher than that in the first insulating layer 382. It should be noted that impurity ions implanted into the bottom of the contact hole are not limited to fluoride ions. The impurity ions implanted into the bottom of the contact hole may be, for example, boron ions (B⁺). In addition, the second insulating layer 384 may be made of silicate glass containing boron, which is different from the material of the first insulating layer 382. Accordingly, the second insulating layer 384 may have a higher boron concentration than the first insulating layer 382.

The intervening layer 66 is provided above the interlayer dielectric film 38. The intervening layer 66 may be in contact with the second insulating layer 384. A thickness of the intervening layer 66 may be smaller than a thickness of the interlayer dielectric film 38. The thickness of the intervening layer 66 may be smaller than a thickness of the second insulating layer 384. The thickness of the intervening layer 66 above the interlayer dielectric film 38 may be 3 nm or more and 20 nm or less, and more preferably, 5 nm or more and 10 nm or less.

A fluorine concentration or a boron concentration in the intervening layer 66 may be lower than a fluorine concentration or a boron concentration at an upper surface of the interlayer dielectric film 38. As described above, when impurity ions such as fluoride ions or boron ions are implanted into the bottom of the contact hole 54 in order to form the plug region 19, the fluorine concentration or the boron concentration at the upper surface of the interlayer dielectric film 38 may increase. The fluorine concentration or the boron concentration in the intervening layer 66 may be lower than the fluorine concentration or the boron concentration at the upper surface of the interlayer dielectric film 38, which has increased due to the implantation of the impurity ions.

The intervening layer 66 may contain titanium nitride. It may be formed of a same material as that of the second barrier metal portion 62, which will be described later. For example, the intervening layer 66 is formed by sputtering titanium nitride above the interlayer dielectric film 38.

The intervening layer 66 may include a silicon oxide film. The intervening layer 66 may include an LTO film, or may include an HTO film. For example, the intervening layer 66 is formed by depositing an LTO film or an HTO film above the interlayer dielectric film 38. As another example, the intervening layer 66 may include a tetra eth oxy silane (TEOS) film. For example, the intervening layer 66 is formed by depositing the TEOS film above the interlayer dielectric film 38 using Plasma Enhanced CVD.

It should be noted that the intervening layer 66 may be made of a material other than titanium nitride or silicon oxide film. For example, the intervening layer 66 may contain silicon nitride, or may contain titanium oxide.

The barrier metal layer 60 is provided above the intervening layer 66. The barrier metal layer 60 may include a predetermined electrically conductive metal. For example, the barrier metal layer 60 contains at least one of titanium, cobalt, nickel, tantalum, magnesium, vanadium, lanthanum, palladium, or zirconium. The barrier metal layer 60 may include a metal that reacts with a base layer to form an alloy layer. In the present example, the barrier metal layer 60 may include a metal that reacts with silicon to form a silicide. The barrier metal layer 60 in the present example includes a first barrier metal portion 61 and a second barrier metal portion 62.

The first barrier metal portion 61 is provided above the intervening layer 66. The first barrier metal portion 61 includes a predetermined electrically conductive metal. The first barrier metal portion 61 may include a predetermined electrically conductive metal single-layer film. For example, the first barrier metal portion 61 contains titanium. For example, the first barrier metal portion 61 is formed by sputtering titanium above the intervening layer 66.

The second barrier metal portion 62 is provided above the first barrier metal portion 61. The second barrier metal portion 62 includes a predetermined electrically conductive material. The second barrier metal portion 62 may include a predetermined electrically conductive metal oxide film. For example, the second barrier metal portion 62 contains titanium nitride. For example, the second barrier metal portion 62 is formed by sputtering titanium nitride above the first barrier metal portion 61.

For example, the barrier metal layer 60 is formed by sputtering titanium above the intervening layer 66, then sputtering titanium nitride above the titanium, and subsequently performing sintering. During a sintering process, at least a part of the titanium may be nitrided to form titanium nitride. That is, the second barrier metal portion 62 may contain titanium nitride formed by sputtering, may contain titanium nitride formed by sintering, or may include both the titanium nitride formed by sputtering and the titanium nitride formed by sintering.

The titanium nitride formed by sintering has a higher density than the titanium nitride formed by sputtering. As described above, the intervening layer 66 may contain the titanium nitride formed by sputtering. In this case, the second barrier metal portion 62 may contain titanium nitride having a higher density than the titanium nitride contained in the intervening layer 66.

The intervening layer 66, the first barrier metal portion 61, and the second barrier metal portion 62 may be provided above the interlayer dielectric film 38 and at the sidewall of the contact hole 54. For example, after the contact hole 54 is formed in the interlayer dielectric film 38, the intervening layer 66, the first barrier metal portion 61, and the second barrier metal portion 62 are formed. Accordingly, the intervening layer 66, the first barrier metal portion 61, and the second barrier metal portion 62 may be provided at the sidewall of the contact hole 54. It should be noted, however, that the order of formation of the contact hole 54, the intervening layer 66, the first barrier metal portion 61, and the second barrier metal portion 62 is not limited thereto. A method for manufacturing the semiconductor apparatus 100 will be described in detail later.

The plug layer 64 may be provided in contact with the second barrier metal portion 62 in the contact hole 54. It should be noted that the plug layer 64 may also be provided in contact with the second barrier metal portion 62 above the interlayer dielectric film 38 outside the contact hole 54. The plug layer 64 may be omitted, and the emitter electrode 52 may fill the interior of the contact hole 54.

The front-surface-side metal layer 53 is provided above the barrier metal layer 60. In the present example, the emitter electrode 52, which is an example of the front-surface-side metal layer 53, is provided above the barrier metal layer 60. The emitter electrode 52 may be provided above the second barrier metal portion 62. The emitter electrode 52 may be provided above the plug layer 64.

In the semiconductor apparatus 100 in the present example, the barrier metal layer 60 is provided between the interlayer dielectric film 38 and the front-surface-side metal layer 53. This makes it possible to suppress ion penetration from the front-surface-side metal layer 53 or a package material used in mounting and to prevent ions from reaching the gate dielectric film 42, thereby preventing a decrease in a threshold voltage of the semiconductor apparatus 100.

The silicide layer 63 is provided above the silicon layer 110 in the contact hole 54. The silicide layer 63 is an example of an alloy layer provided above the base layer. The silicide layer 63 in the present example is provided above the semiconductor substrate 10, which is an example of the silicon layer 110. The silicide layer 63 may be provided on the semiconductor substrate 10. For example, the silicide layer 63 is formed as a result of a material of the barrier metal layer 60, which is deposited at the bottom of the contact hole 54 during a process of forming the barrier metal layer 60, reacting with silicon of the semiconductor substrate 10 during the sintering process to form a silicide. At this time, the silicide layer 63 may be formed to a position deeper than the front surface 21. Thus, the barrier metal layer 60 may include a metal that reacts with silicon to form a silicide.

When the intervening layer 66 contains titanium nitride, the silicide layer 63 may be formed as a result of a material of the intervening layer 66 reacting with the silicon of the semiconductor substrate 10 during the sintering process to form a silicide. When the intervening layer 66 includes a silicon oxide film, the silicide layer 63 may be formed as a result of the material of the barrier metal layer 60, which is deposited at the bottom of the contact hole 54 during the process of forming the barrier metal layer 60, reacting with silicon of the intervening layer 66 during a sintering process to form a silicide. That is, the silicide layer 63 may include a product of a reaction between the barrier metal layer 60 and the semiconductor substrate 10, may include a product of a reaction between the barrier metal layer 60 and the intervening layer 66, or may include a product of a reaction between the intervening layer 66 and the semiconductor substrate 10.

The barrier metal layer 60 may be in contact with the silicide layer 63. The barrier metal layer 60 in the present example is in contact with the silicide layer 63 at the bottom of the contact hole 54. The second barrier metal portion 62 may be in contact with the silicide layer 63. In another example, the first barrier metal portion 61 may remain between the silicide layer 63 and the second barrier metal portion 62. As described above, the silicide layer 63 may be formed through silicidation of the material of the barrier metal layer 60. Accordingly, the barrier metal layer 60 may be in contact with the silicide layer 63.

The plug region 19 may be provided at a surface of the silicon layer 110 below the silicide layer 63. This makes it possible to reduce contact resistance between the silicide layer 63 and a P type region such as the contact region 15, as in the example shown in FIG. 3B.

When the first barrier metal portion is provided in contact with the interlayer dielectric film, adhesion between the first barrier metal portion and the interlayer dielectric film may be poor, and delamination between the first barrier metal portion and the interlayer dielectric film may occur due to stress caused by wire bonding or the like. For example, when the first barrier metal portion includes a metal that reacts with silicon to form a silicide, and the interlayer dielectric film contains silicate glass, the adhesion between the first barrier metal portion and the interlayer dielectric film may deteriorate. In addition, when the plug region is formed in order to reduce contact resistance between the silicide layer and the silicon layer, and the fluorine concentration or the boron concentration in the interlayer dielectric film is high due to the implantation of the impurity ions for forming the plug region, the adhesion may particularly deteriorate.

In the semiconductor apparatus 100 in the present example, the intervening layer 66 is provided above the interlayer dielectric film 38, and the barrier metal layer 60 is provided above the intervening layer 66. That is, the intervening layer 66 is provided between the barrier metal layer 60 and the interlayer dielectric film 38. This makes it possible to improve interlayer adhesion and prevent the delamination. Therefore, the semiconductor apparatus 100 in the present example can prevent the delamination while suppressing the ion penetration from the front-surface-side metal layer 53 or the package material used in mounting and preventing ions from reaching the gate dielectric film 42 by mean of the barrier metal layer 60.

In addition, since the intervening layer 66 is provided between the barrier metal layer 60 and the interlayer dielectric film 38 in the semiconductor apparatus 100 in the present example, even when the fluorine concentration or the boron concentration in the interlayer dielectric film 38 is high, it is possible to improve the interlayer adhesion and prevent the delamination. Therefore, the semiconductor apparatus 100 in the present example can prevent the delamination while reducing contact resistance between the silicide layer 63 and the silicon layer 110.

In addition, the first barrier metal portion may be removed in order to prevent a decrease in the adhesion. Since the intervening layer 66 is provided between the barrier metal layer 60 and the interlayer dielectric film 38 in the semiconductor apparatus 100 in the present example, it is possible to improve the interlayer adhesion and prevent the delamination by a process simpler than removing the first barrier metal portion.

For example, when the intervening layer 66 contains titanium nitride, the first barrier metal portion 61 contains titanium, and the second barrier metal portion 62 contains titanium nitride, adhesion between the intervening layer 66 containing titanium nitride and the interlayer dielectric film 38 containing silicate glass, and adhesion between the intervening layer 66 containing titanium nitride and the first barrier metal portion 61 containing titanium are higher than adhesion between the first barrier metal portion 61 containing titanium and the interlayer dielectric film 38 containing silicate glass. Therefore, it is possible to improve the interlayer adhesion and prevent the delamination.

As another example, when the intervening layer 66 contains silicon oxide film, the first barrier metal portion 61 contains titanium, and the second barrier metal portion 62 contains titanium nitride, adhesion between the intervening layer 66 containing silicon oxide film and the interlayer dielectric film 38 containing silicate glass, and adhesion between the intervening layer 66 containing silicon oxide film and the first barrier metal portion 61 containing titanium are higher than the adhesion between the first barrier metal portion 61 containing titanium and the interlayer dielectric film 38 containing silicate glass. Therefore, it is possible to improve the interlayer adhesion and prevent the delamination.

As described above, the thickness of the intervening layer 66 above the interlayer dielectric film 38 may be 3 nm or more and 20 nm or less. When the thickness of the intervening layer 66 above the interlayer dielectric film 38 is less than 3 nm, it may be difficult to form a thin intervening layer 66, or improvement in the interlayer adhesion may not be obtained. Therefore, the thickness of the intervening layer 66 above the interlayer dielectric film 38 may be 3 nm or more.

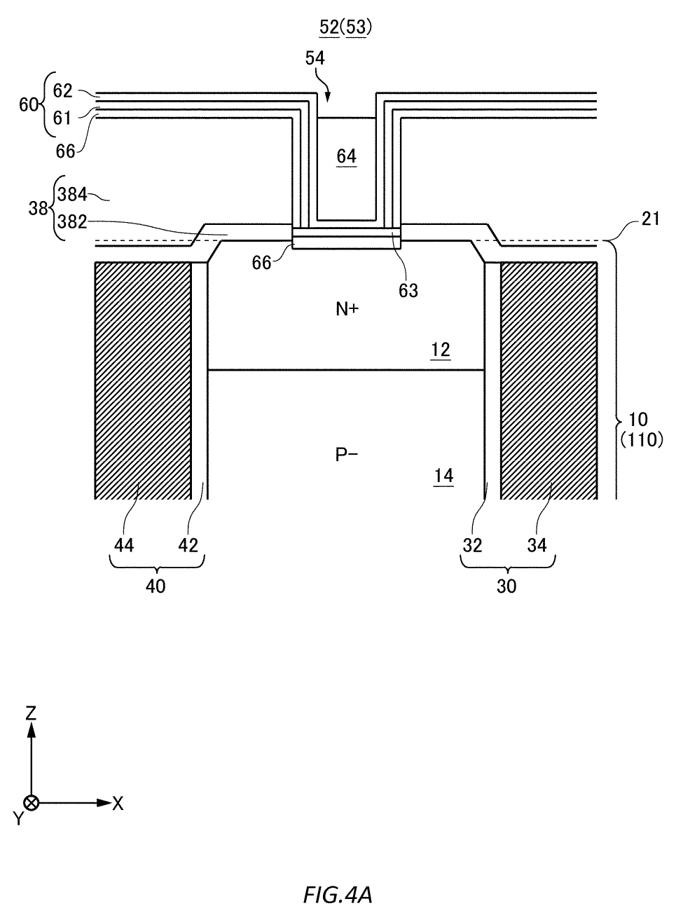

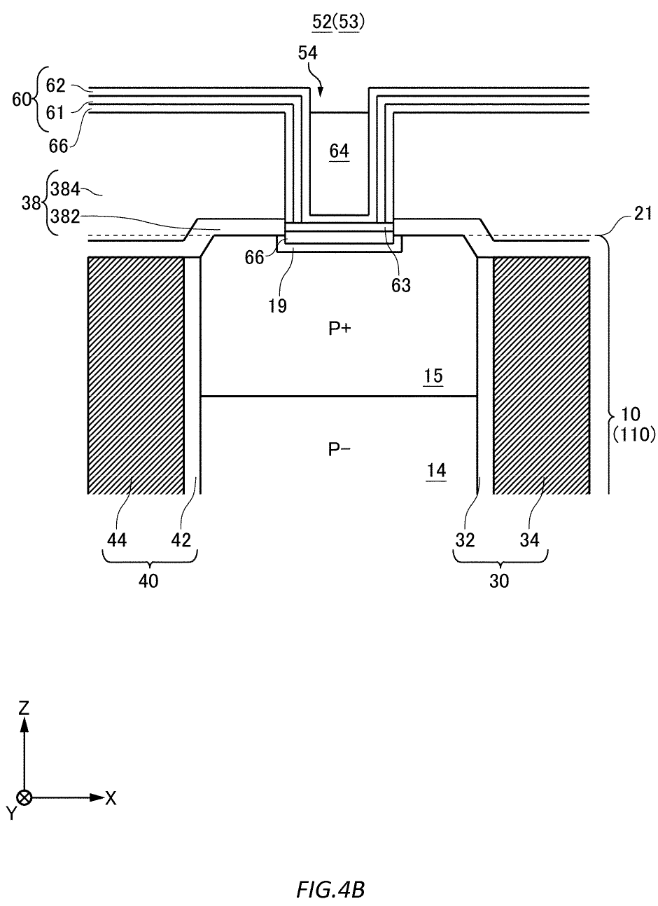

FIG. 4A is an enlarged view of a cross section of the semiconductor apparatus 100. The cross section in the present example is the XZ cross section which passes through the emitter region 12 at the front surface 21 of the semiconductor substrate 10. The semiconductor apparatus 100 in the present example differs from that in the example shown in FIG. 3A in that the intervening layer 66 is provided between the silicide layer 63 and the silicon layer 110. In the present example, differences with the example shown in FIG. 3A will be particularly described, and other configurations may be the same as those in the example shown in FIG. 3A.

The intervening layer 66 in the present example includes a silicon oxide film. The intervening layer 66 may contain titanium nitride. At least a part of the intervening layer 66 may remain without being used for the silicidation of the material of the barrier metal layer 60 during the sintering process. In this case, the silicide layer 63 may be provided above the silicon layer 110 with the intervening layer 66 interposed therebetween. Since a very thin intervening layer 66 remaining at the bottom of the contact hole 54 does not lead to a large increase in resistance between the plug layer 64 and the silicon layer 110, the intervening layer 66 may remain at the bottom of the contact hole 54. It should be noted that the remaining intervening layer 66 may be positioned below the silicide layer 63, or may be positioned within the silicide layer 63.

As described above, the thickness of the intervening layer 66 above the interlayer dielectric film 38 may be 3 nm or more and 20 nm or less. When the thickness of the intervening layer 66 above the interlayer dielectric film 38 increases, the thickness of the intervening layer 66 remaining at the bottom of the contact hole 54 also increases. For example, when the thickness of the intervening layer 66 above the interlayer dielectric film 38 is greater than 20 nm, an increase in the thickness of the intervening layer 66 remaining at the bottom of the contact hole 54 may lead to an increase in the resistance between the plug layer 64 and the silicon layer 110. Therefore, the thickness of the intervening layer 66 above the interlayer dielectric film 38 may be 20 nm or less. It should be noted that if the intervening layer 66 is deposited such that the thickness of the intervening layer 66 above the interlayer dielectric film 38 differs from the thickness of the intervening layer 66 within the contact hole 54, for example, when the intervening layer 66 within the contact hole 54 is thinned or removed during manufacturing, the thickness of the intervening layer 66 above the interlayer dielectric film 38 is not limited to 20 nm or less and may be greater, even in the example shown in FIGS. 3A, 3B or 4A, .

FIG. 4B is an enlarged view of a cross section of the semiconductor apparatus 100. The cross section in the present example differs from the cross section in FIG. 4A in that it passes through the contact region 15 at the front surface 21. Other configurations may be the same as those in the example shown in FIG. 4A.

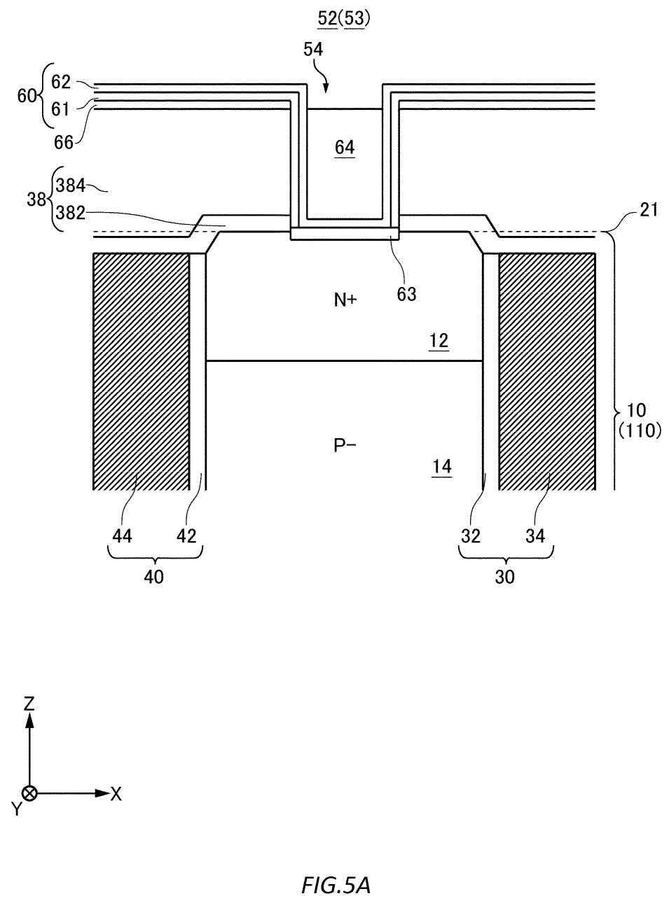

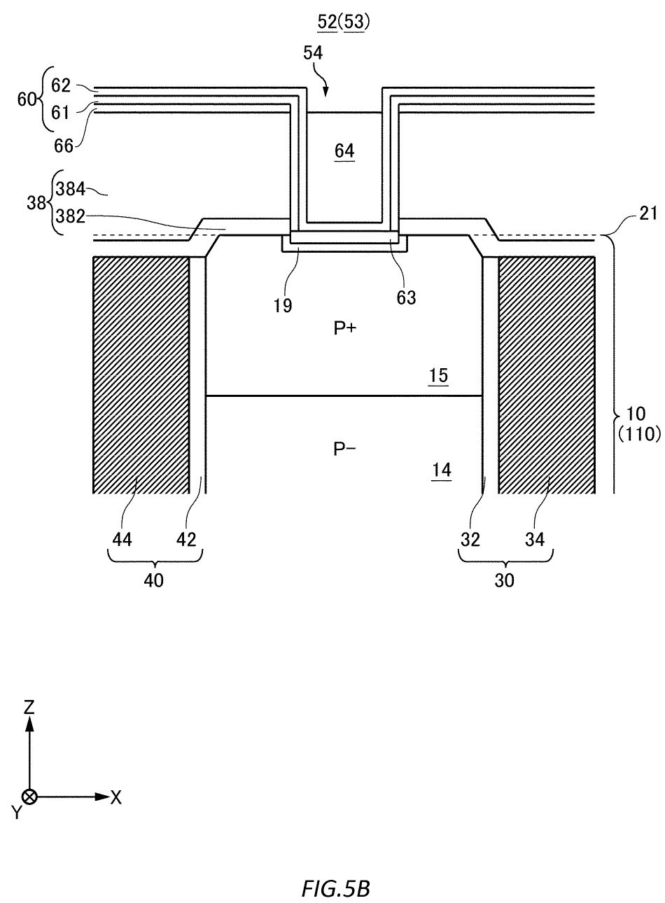

FIG. 5A is an enlarged view of a cross section of the semiconductor apparatus 100. The cross section in the present example is the XZ cross section which passes through the emitter region 12 at the front surface 21 of the semiconductor substrate 10. The semiconductor apparatus 100 in the present example differs from that in the example shown in FIG. 3A in that the intervening layer 66 is not provided at the sidewall of the contact hole 54. In the present example, differences with the example shown in FIG. 3A will be particularly described, and other configurations may be the same as those in the example shown in FIG. 3A.

The first barrier metal portion 61 and the second barrier metal portion 62 may be provided above the interlayer dielectric film 38 and at the sidewall of the contact hole 54. The first barrier metal portion 61 may be in contact with the sidewall of the contact hole 54.

For example, after the intervening layer 66 is formed above the interlayer dielectric film 38, the contact hole 54 is formed. Subsequently, the first barrier metal portion 61 and the second barrier metal portion 62 may be formed. Accordingly, the intervening layer 66 may not be provided at the sidewall of the contact hole 54, and the first barrier metal portion 61 and the second barrier metal portion 62 may be provided at the sidewall of the contact hole 54. Therefore, the first barrier metal portion 61 may in contact with the sidewall of the contact hole 54. It should be noted, however, that the order of formation of the contact hole 54, the intervening layer 66, the first barrier metal portion 61, and the second barrier metal portion 62 is not limited thereto. A method for manufacturing the semiconductor apparatus 100 will be described in detail later.

In the semiconductor apparatus 100 in the present example, the intervening layer 66 is also provided above the interlayer dielectric film 38, and the barrier metal layer 60 is provided above the intervening layer 66. That is, the intervening layer 66 is provided between the barrier metal layer 60 and the interlayer dielectric film 38. This makes it possible to improve the interlayer adhesion and prevent the delamination. Therefore, the semiconductor apparatus 100 in the present example can prevent the delamination while suppressing the ion penetration from the front-surface-side metal layer 53 or the package material used in mounting and preventing ions from reaching the gate dielectric film 42 by mean of the barrier metal layer 60.

The delamination caused by low adhesion between the first barrier metal portion and the interlayer dielectric film is largely attributable to the upper surface of the interlayer dielectric film. Therefore, in the semiconductor apparatus 100 in the present example, even if the intervening layer 66 is not provided at the sidewall of the contact hole 54, the intervening layer 66 is provided between the barrier metal layer 60 and the interlayer dielectric film 38 above the interlayer dielectric film 38, whereby it is possible to improve the interlayer adhesion and prevent the delamination.

The thickness of the intervening layer 66 above the interlayer dielectric film 38 may be 3 nm or more. In the present example, the thickness of the intervening layer 66 above the interlayer dielectric film 38 may be 20 nm or less, may be 100 nm or less, or may be 200 nm or less. In the present example, since the intervening layer 66 is not formed within the contact hole, an increase in the thickness of the intervening layer 66 above the interlayer dielectric film 38 does not lead to the increase in the resistance between the plug layer 64 and the silicon layer 110 at the bottom of the contact hole.

FIG. 5B is an enlarged view of a cross section of the semiconductor apparatus 100. The cross section in the present example differs from the cross section in FIG. 5A in that it passes through the contact region 15 at the front surface 21. Other configurations may be the same as those in the example shown in FIG. 5A.

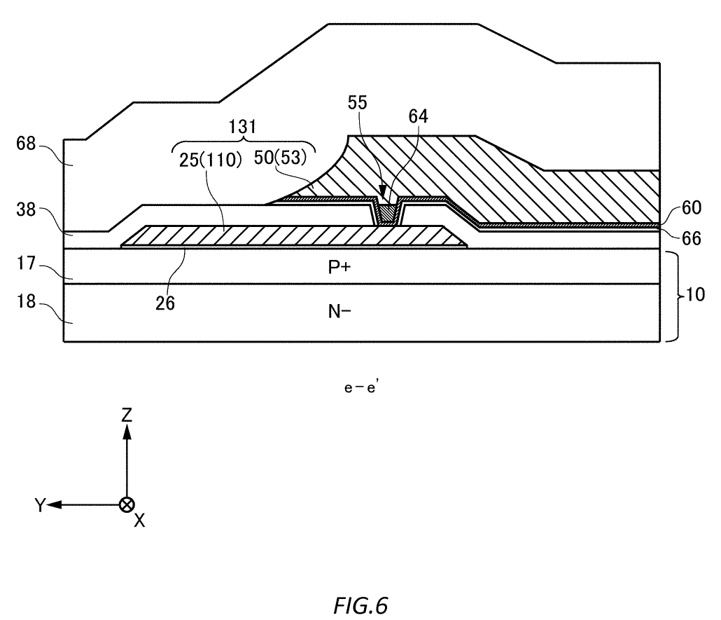

FIG. 6 shows an example of the cross section e-e’ in FIGS. 1A or 2B . The cross section e-e’ is a YZ plane passing through the inter-active-portion gate wiring 131. The inter-active-portion gate wiring 131 in the present example includes the gate metal layer 50 and a connection section 25. The gate metal layer 50 is an example of the front-surface-side metal layer 53. The connection section 25 is an example of the silicon layer 110. The silicon layer 110 in the present example contains polysilicon. A covering layer 68 made of a material such as polyimide may be provided above the inter-active-portion gate wiring 131.

The connection section 25 may be provided above the semiconductor substrate 10 with an insulating layer 26 interposed therebetween. The insulating layer 26 may be deposited simultaneously with the gate dielectric film 42 and the dummy dielectric film 32. The connection section 25 is electrically connected to the gate conductive portion 44. It should be noted that, although the cross section of the inter-active-portion gate wiring 131 has been described in the present example, the gate metal layer 50 and the connection section 25 may also be similarly provided for the outer circumferential gate wiring 130.

The gate metal layer 50 is provided above the semiconductor substrate 10. A part of the front-surface-side metal layer 53 may be provided so as to overlap with the silicon layer 110 in the depth direction of the semiconductor substrate 10. The gate metal layer 50 in the present example is electrically connected to the connection section 25 via the contact hole 55 provided above the connection section 25. The gate metal layer 50 may be formed of a same material as that of the emitter electrode 52, or may be formed of a material different from that of the emitter electrode 52.

Configurations between the interlayer dielectric film 38 and the front-surface-side metal layer 53 as well as in the vicinity of the contact hole 55, may be similar to configurations between the interlayer dielectric film 38 and the front-surface-side metal layer 53 as well as in the vicinity of the contact hole 54 in the examples described in FIGS. 3A-5B . That is, the semiconductor apparatus 100 includes the intervening layer 66 provided above the interlayer dielectric film 38, the barrier metal layer 60 provided above the intervening layer 66, and the silicide layer 63 provided above the silicon layer 110. It should be noted that the contact hole 55 may also be similarly provided for the outer circumferential gate wiring 130. As described above, even in an area above which wire bonding is not directly performed, or in an area spaced apart from the MOS gate structure, between the interlayer dielectric film 38 and the front-surface-side metal layer 53 as well as in an upper part in the vicinity of the contact hole, there may be provided the intervening layer 66 provided above the interlayer dielectric film 38, the barrier metal layer 60 provided above the intervening layer 66, and the silicide layer 63 provided above the silicon layer 110.

In FIG. 6, the intervening layer 66 is not provided on the upper surface of the interlayer dielectric film 38 not covered with the gate metal layer 50 and the barrier metal layer 60. When the intervening layer 66 is made of an electrically conductive material such as titanium nitride, the intervening layer 66 is not provided on the upper surface of the interlayer dielectric film 38 between the gate metal layer 50 and another front-surface-side metal layer 53. As a result, the respective front-surface-side metal layers are electrically separated from each other. On the other hand, when the intervening layer 66 is made of an insulating material such as silicon oxide film, the intervening layer 66 may be continuously provided on the upper surface of the interlayer dielectric film 38 up to below the emitter electrode 52 or another metal layer outside the range shown in FIG. 6. Even in such a case, the gate metal layer 50 and another front-surface-side metal layer 53 such as the emitter electrode 52 are electrically separated from each other.

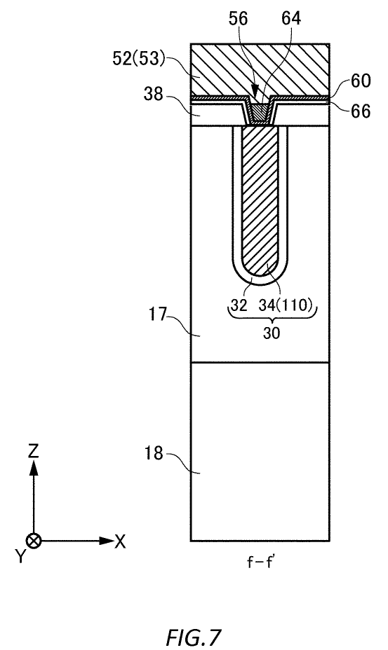

FIG. 7 shows an example of the cross section f-f’ in FIGS. 1A or 2B . The cross section f-f’ is the XZ plane passing through the dummy trench portion 30.

The silicon layer 110 may be provided in the semiconductor substrate 10. The dummy conductive portion 34 in the present example is an example of the silicon layer 110 provided in the semiconductor substrate 10. The contact hole 56 may be provided above the dummy conductive portion 34. The contact hole 56 functions as a contact hole for connecting the emitter electrode 52 and the dummy conductive portion 34. The emitter electrode 52 is an example of the front-surface-side metal layer 53.

Configurations between the interlayer dielectric film 38 and the front-surface-side metal layer 53 as well as in the vicinity of the contact hole 56, may be similar to the configurations between the interlayer dielectric film 38 and the front-surface-side metal layer 53 as well as in the vicinity of the contact hole 54 in the examples described in FIGS. 3A-5B . That is, the semiconductor apparatus 100 includes the intervening layer 66 provided above the interlayer dielectric film 38, the barrier metal layer 60 provided above the intervening layer 66, and the silicide layer 63 provided above the silicon layer 110.

In FIGS. 1A,2B,6 and 7, the gate conductive portion 44 and the gate metal layer 50 are connected to each other via the connection section 25 and the contact hole 55, and the dummy conductive portion 34 and the emitter electrode 52 are connected to each other via the contact hole 56. The gate conductive portion 44 and the gate metal layer 50 may be connected to each other via the contact hole 55 instead of being connected via the connection section 25, and the dummy conductive portion 34 and the emitter electrode 52 may be connected to each other via the connection section 25 and the contact hole 56.

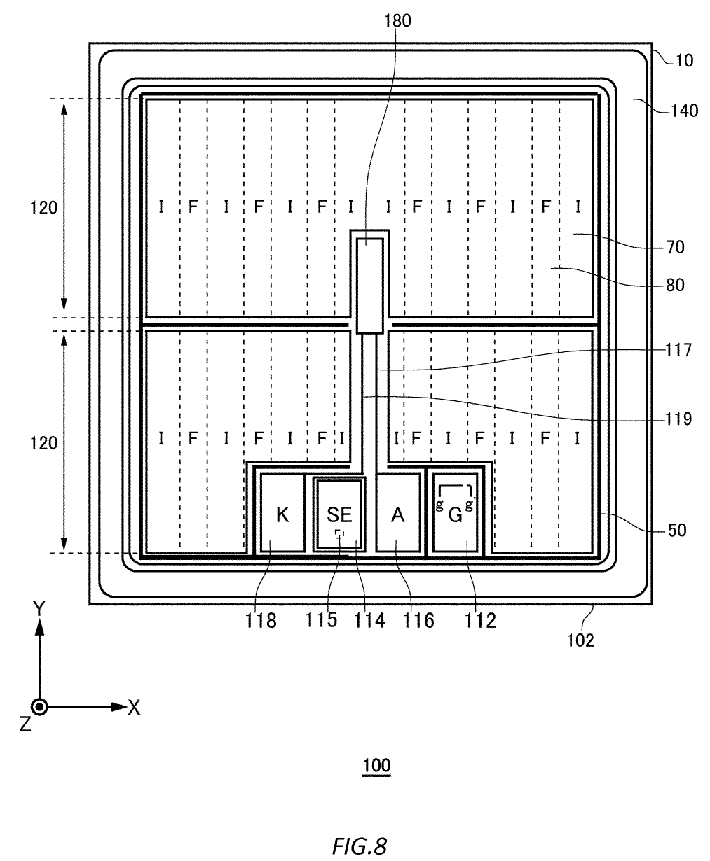

FIG. 8 shows an example of a top view of the semiconductor apparatus 100 including the temperature sensing unit 180. The semiconductor apparatus 100 in the present example includes the gate pad 112, a sensing electrode 114, an anode pad 116, and a cathode pad 118.

The front-surface-side metal layer 53 may include the emitter electrode 52, the gate pad 112, the sensing electrode 114, the anode pad 116, and the cathode pad 118, which are partially exposed from the covering layer 68. The front-surface-side metal layer 53 may be electrically connected to an electrically conductive member such as a lead frame. The front-surface-side metal layer 53 may be electrically connected to an electrode external to the semiconductor apparatus 100 by wire bonding or the like. In addition, the front-surface-side metal layer 53 may include a wiring such as the gate metal layer 50 covered with the covering layer 68. It should be noted that, the number and position of at least one front-surface-side metal layer 53 are not limited to the present example.

The sensing electrode 114 is electrically connected to a current sensing unit 115 provided below the sensing electrode 114. The sensing electrode 114 detects a current flowing through the current sensing unit 115. The current sensing unit 115 detects a current flowing through the transistor portion 70. The current sensing unit 115 has a structure corresponding to the transistor portion 70, simulates operation of the transistor portion 70, and allows a current proportional to the current flowing through the transistor portion 70 to flow therethrough. By using the current sensing unit 115, the current flowing through the transistor portion 70 can be monitored. Configurations between the interlayer dielectric film 38 of the current sensing unit 115, and the sensing electrode 114 and the gate metal layer 50 as well as in the vicinity of the contact hole, may be similar to configurations between the interlayer dielectric film 38 of the transistor portion 70, and the emitter electrode 52 and the gate metal layer 50 as well as in the vicinity of the contact hole.

The temperature sensing unit 180 is provided on top of or within the semiconductor substrate 10. The temperature sensing unit 180 in the present example is provided on the well region 17 between the transistor portions 70 in the middle of the semiconductor apparatus 100. The temperature sensing unit 180 senses the temperature of the active portion 120. The temperature sensing unit 180 may include a diode formed of monocrystalline or polycrystalline silicon. The temperature sensing unit 180 is used for detecting a temperature of the semiconductor apparatus 100 and protecting the semiconductor chip from overheating. The temperature sensing unit 180 is connected to a constant current source. When the temperature of the semiconductor apparatus 100 changes, a forward voltage of a current flowing through the temperature sensing unit 180 changes. The semiconductor apparatus 100 can detect the temperature based on the change in the forward voltage of the temperature sensing unit 180. The temperature sensing unit 180 has its long side along the Y axis direction and its short side along the X axis direction, but is not limited thereto.

The anode pad 116 is electrically connected to an anode region of the temperature sensing unit 180. The anode pad 116 is electrically connected to the anode region of the temperature sensing unit 180 by an anode wiring 117.

The cathode pad 118 is electrically connected to a cathode region of the temperature sensing unit 180. The cathode pad 118 is electrically connected to the cathode region of the temperature sensing unit 180 by a cathode wiring 119.

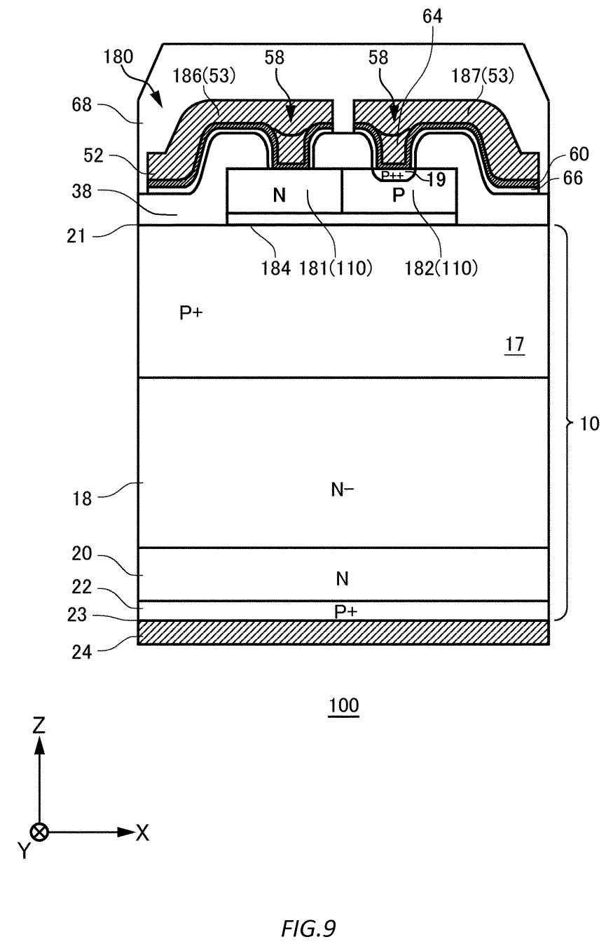

FIG. 9 is an example of an enlarged view of a cross section in the temperature sensing unit 180. The temperature sensing unit 180 in the present example includes a cathode electrode 186, an anode electrode 187, a cathode region 181, and an anode region 182. The cathode electrode 186 and the anode electrode 187 are examples of the front-surface-side metal layer 53. The cathode region 181 and the anode region 182 are examples of the silicon layer 110. The covering layer 68 made of a material such as polyimide may be provided above the temperature sensing unit 180.

The temperature sensing unit 180 includes the diode provided in the semiconductor substrate 10. The temperature sensing unit 180 utilizes a current-voltage characteristic of the diode, which changes depending on the temperature, to detect the temperature of the semiconductor apparatus 100. The temperature sensing unit 180 is arranged above the semiconductor substrate 10 with a dielectric film 184 interposed therebetween. The dielectric film 184 may be a deposited film such as an HTO film, or may be a film formed through thermal oxidation of the semiconductor substrate 10, or the like. The temperature sensing unit 180 may be provided above the well region 17.

The cathode region 181 and the anode region 182 constitute a PN diode. For example, the cathode region 181 is formed of an N type semiconductor and functions as the cathode of the PN diode. The anode region 182 is formed of a P type semiconductor and functions as the anode of the PN diode. The cathode region 181 and the anode region 182 are provided on the dielectric film 184. The material of the cathode region 181 and the anode region 182 may be polysilicon.

The cathode electrode 186 is electrically connected to the cathode region 181 via the contact hole 58. The cathode electrode 186 may be formed of the same material as that of the emitter electrode 52. The cathode electrode 186 is electrically connected to the cathode pad 118 by the cathode wiring 119.

The anode electrode 187 is electrically connected to the anode region 182 via the contact hole 58. The plug region 19 may be formed at the bottom of the contact hole 58 above the anode region 182. The anode electrode 187 may be formed of the same material as that of the emitter electrode 52. The anode electrode 187 is electrically connected to the anode pad 116 by the anode wiring 117.

The interlayer dielectric film 38 is provided on the upper surface of the cathode region 181 and the anode region 182. The contact hole 58 may be formed in the interlayer dielectric film 38 of the temperature sensing unit 180.

Device regions such as the transistor portion 70 and the diode portion 80 may be provided below the temperature sensing unit 180. The temperature sensing unit 180 in the present example is provided so as to be enclosed by the transistor portion 70. It should be noted, however, that the temperature sensing unit 180 may be provided so as to be enclosed by the diode portion 80, or may be provided in a region apart from the active portion 120, in the vicinity of the edge termination structure portion 140. The collector region 22 is provided below the temperature sensing unit 180 in the present example, but a high-concentration region such as the collector region 22 may not be formed below the temperature sensing unit 180.

Configurations between the interlayer dielectric film 38 and the front-surface-side metal layer 53 as well as in the vicinity of the contact hole 58, may be similar to the configurations between the interlayer dielectric film 38 and the front-surface-side metal layer 53 as well as in the vicinity of the contact hole 54 in the examples described in FIGS. 3A-5B . That is, the semiconductor apparatus 100 includes the intervening layer 66 provided above the interlayer dielectric film 38, the barrier metal layer 60 provided above the intervening layer 66, and the silicide layer 63 provided above the silicon layer 110.

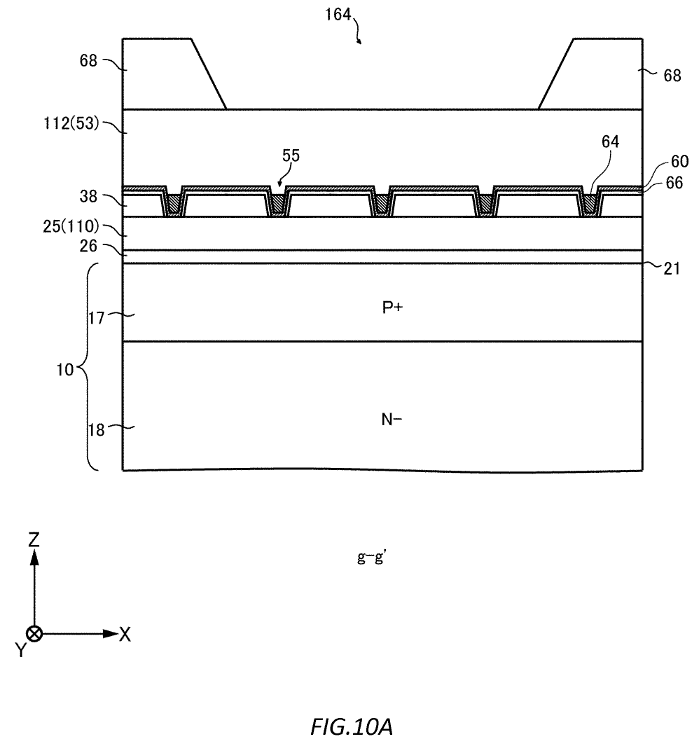

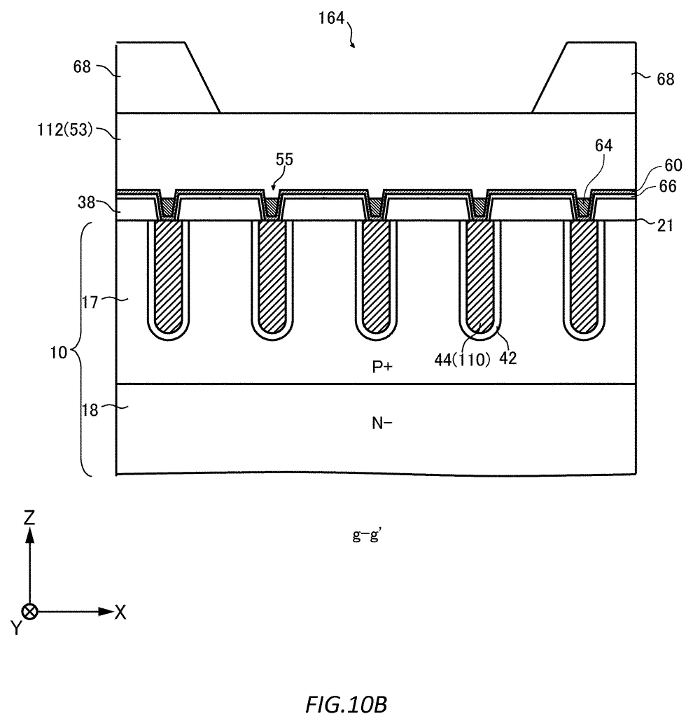

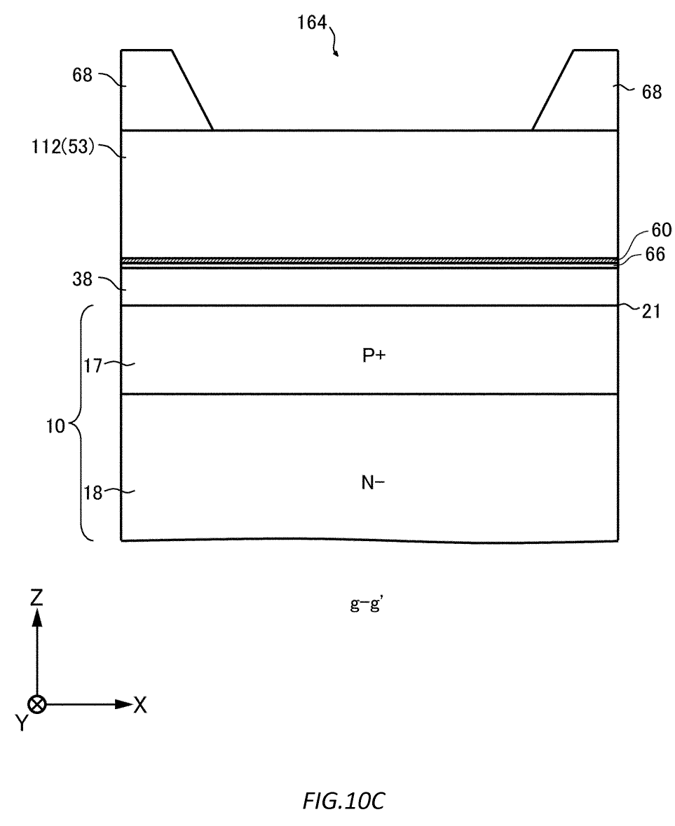

FIG. 10A shows an example of the cross section g-g’ in FIG. 8. The cross section g-g’ is the XZ plane passing through the gate pad 112. The semiconductor apparatus 100 in the present example includes, in the cross section g-g’, the semiconductor substrate 10, the connection section 25, the interlayer dielectric film 38, the intervening layer 66, the barrier metal layer 60, the plug layer 64, and the gate pad 112. The connection section 25 is an example of the silicon layer 110. The gate pad 112 is an example of the front-surface-side metal layer 53.

The covering layer 68 made of a material such as polyimide may be provided over a part of the area above the gate pad 112. A region of an upper surface of the gate pad 112 that is exposed without being covered with the covering layer 68 is referred to as an opening region 164.

The connection section 25 may be provided above the semiconductor substrate 10 with the insulating layer 26 interposed therebetween. It should be noted that the connection section 25 may be directly connected to the gate conductive portion 44 that extends to the active portion 120 outside the range shown in FIG. 10A, and in this case, the connection section 25 and the insulating layer 26 may be formed simultaneously with the gate conductive portion 44 and the gate dielectric film 42. In addition, the connection section 25 may not be directly connected to the gate conductive portion 44 that extends to the active portion 120, and in this case, the connection section 25 and the insulating layer 26 may be formed simultaneously with, or separately from, the gate conductive portion 44 and the gate dielectric film 42.

The gate pad 112 is provided above the semiconductor substrate 10. The gate pad 112 may be provided so as to overlap with the connection section 25 in the depth direction of the semiconductor substrate 10. The gate pad 112 in the present example is electrically connected to the connection section 25 via the contact hole 55 provided above the connection section 25. The gate pad 112 may be formed of the same material as that of the emitter electrode 52, or may be formed of a material different from that of the emitter electrode 52. The gate pad 112 may be extended outside the opening region 164, to function as the inter-active-portion gate wiring 131 or as the gate metal layer 50 of the outer circumferential gate wiring 130.

The configurations between the interlayer dielectric film 38 and the front-surface-side metal layer 53 as well as in the vicinity of the contact hole 55, may be similar to the configurations between the interlayer dielectric film 38 and the front-surface-side metal layer 53 as well as in the vicinity of the contact hole 54 in the examples described in FIGS. 3A-5B . That is, the semiconductor apparatus 100 includes the intervening layer 66 provided above the interlayer dielectric film 38, the barrier metal layer 60 provided above the intervening layer 66, and the silicide layer 63 provided above the silicon layer 110.

FIG. 10B shows an example of the cross section g-g’ in FIG. 8. The semiconductor apparatus 100 in the present example differs from that in the example shown in FIG. 10A in that it includes the gate trench portion 40 below the opening region 164 of the gate pad 112. In the present example, differences with the example shown in FIG. 10A will be particularly described, and other configurations may be the same as those in the example shown in FIG. 10A.

The gate trench portion 40 in the range overlapping with the gate pad 112 is provided in the well region 17. The diffusion depth of the well region 17 is deeper than a depth of the gate trench portion 40. In the present example, the entirety of the gate trench portion 40 in the range overlapping with the gate pad 112 is provided in the well region 17 in a top view. This makes it possible to alleviate electric field strength at the bottom of each gate trench portion 40.

The gate pad 112 in the present example is electrically connected to the gate conductive portion 44 via the contact hole 55 provided above the gate conductive portion 44. The gate conductive portion 44 is an example of the silicon layer 110. It should be noted that the gate trench portion 40 in the present example may be extended to the active portion 120, or may not be extended to the active portion 120.

FIG. 10C shows an example of the cross section g-g’ in FIG. 8. The semiconductor apparatus 100 in the present example differs from that in the example shown in FIG. 10A in that the contact hole 55 is not provided over the entirety of the area below the opening region 164 of the gate pad 112. Other configurations may be the same as those in the example shown in FIG. 10A.

In the present example, the entirety of the region below the gate pad 112 is free of the connection section 25 and the insulating layer 26. In another example, the connection section 25 and the insulating layer 26 may be provided between the interlayer dielectric film 38 and the semiconductor substrate 10 over a part or the entirety of the region below the gate pad 112. The configuration between the interlayer dielectric film 38 and the front-surface-side metal layer 53 may be similar to the configuration between the interlayer dielectric film 38 and the front-surface-side metal layer 53 in the examples described in FIGS. 3A-5B . That is, the semiconductor apparatus 100 includes the intervening layer 66 provided above the interlayer dielectric film 38 and the barrier metal layer 60 provided above the intervening layer 66.

In FIGS. 10A-10C , the description has been given using the examples in which the area below the covering layer 68 is similar to the area below the opening region 164, but these areas may have respective different structures. That is, for example, the structure below the covering layer 68 may be the structure shown in FIG. 10A, and the structure below the opening region 164 may be the structure shown in FIG. 10C. In addition, in FIGS. 10A-10C , the description has been given using the gate pad 112 as an example, but the configurations between the interlayer dielectric film 38 and the front-surface-side metal layer 53 as well as in the vicinity of the contact hole, may also be applied to the area below another pad below which no device is provided. In the present example, the configurations may also be similarly applied to a region of the sensing electrode 114 below which the current sensing unit 115 is not provided, to the anode pad 116, and to the cathode pad 118.

It should be noted that, in the above description, the example has been described in which the intervening layer 66 and the barrier metal layer 60 are provided over the entire surface above the interlayer dielectric film 38, but the range over which the intervening layer 66 and the barrier metal layer 60 are provided above the interlayer dielectric film 38 is not limited thereto. For example, in order to suppress variations in characteristics such as a decrease in the threshold voltage of the semiconductor apparatus 100, there may be a case where a region in which the barrier metal layer 60 is provided above the interlayer dielectric film 38 and a region in which the barrier metal layer 60 is not provided above the interlayer dielectric film 38 coexist. In this case, the intervening layer 66 may not be provided in the region in which the barrier metal layer 60 is not provided. In addition, in a region where the effect of stress caused by wire bonding or the like is small, the intervening layer 66 may not be provided.

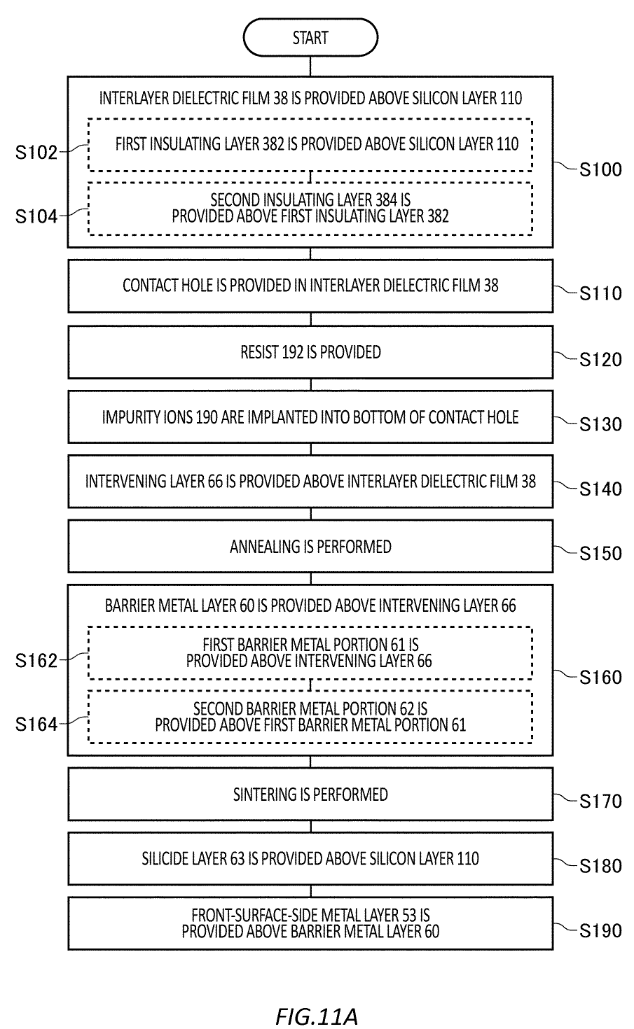

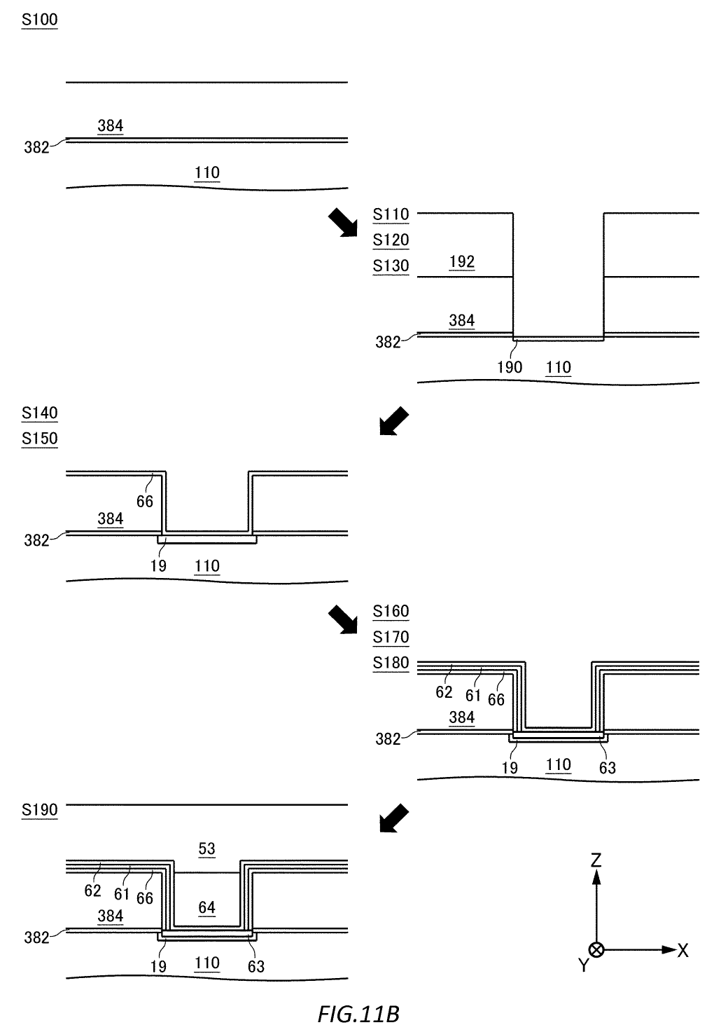

FIG. 11A is a flowchart showing an example of a process of manufacturing the semiconductor apparatus 100. The manufacturing process in the present example is an example of a method for manufacturing a configuration in the vicinity of a contact hole. That is, the process of manufacturing the semiconductor apparatus 100 may include other processes not shown in the flowchart in the present example, such as processes of forming the base region 14, the emitter region 12, the contact region 15, and the like through ion implantation into the semiconductor substrate 10. The contact hole may be the contact hole 54, may be the contact hole 55, may be the contact hole 56, or may be the contact hole 58.

In step S100, the interlayer dielectric film 38 made of silicate glass is provided above the silicon layer 110. The step S100 of providing the interlayer dielectric film 38 may include step S102 of providing the first insulating layer 382 above the silicon layer 110 and step S104 of providing the second insulating layer 384 above the first insulating layer 382. The first insulating layer 382 may be a silicon oxide film, may be an HTO film, or may be an LTO film. The second insulating layer 384 may be a silicate glass, may be a BPSG film, may be a BSG film, or may be a PSG film.

In step S110, a contact hole is provided in the interlayer dielectric film 38. The contact hole may be provided by etching the interlayer dielectric film 38. In step S110, contact holes such as the contact hole 54, the contact hole 55, the contact hole 56, and the contact hole 58 may be formed in the interlayer dielectric film 38. The process of manufacturing the semiconductor apparatus 100 in the present example may include step S110 of providing the contact hole in the interlayer dielectric film 38 after step S100 of providing the interlayer dielectric film 38 and before step S140 of providing the intervening layer 66. Therefore, the process of manufacturing the semiconductor apparatus 100 in the present example may be the process of manufacturing the semiconductor apparatus 100 according to the examples shown in FIGS. 3A-4B .

In step S120, a resist 192 is provided. In step S130, impurity ions 190 are implanted into the bottom of the contact hole in the opening of the resist 192. The process of manufacturing the semiconductor apparatus 100 in the present example may include step S130 of implanting the impurity ions 190 into the bottom of the contact hole after step S110 of providing the contact hole and before step S140 of providing the intervening layer 66. The impurity ions 190 may include halide ions. For example, the halide ions are fluoride ions, and more specifically, boron fluoride ions. By implanting the impurity ions 190, the plug region 19 may be formed later. The bottom of the contact hole in which the plug region 19 is not formed may be covered with the resist 192. It should be noted that the ions implanted into the bottom of the contact hole are not limited to halide ions. The ions implanted into the bottom of the contact hole may be, for example, boron ions.

The impurity ions 190 may be implanted from above the semiconductor substrate 10. The resist 192 may cover a part or the entirety of the interlayer dielectric film 38. When the interlayer dielectric film 38 is not covered with the resist 192, the impurity ions 190 are also implanted into the interlayer dielectric film 38, and a halogen concentration or a boron concentration at the upper surface of the interlayer dielectric film, or a halogen concentration or a boron concentration in the second insulating layer 384 may increase. It should be noted that when electrical connection between an N type impurity region and the front-surface-side metal layer 53 is not hindered even if the impurity ions 190 are implanted into the entire surface of the bottom of the contact hole, step S120 may be omitted. For example, when the bottom surface of the contact hole is positioned below a lower surface of the interlayer dielectric film 38, or when a concentration in the N type impurity region is sufficiently high, the step S120 may be omitted. In addition, the resist 192 is removed after implanting the impurity ions 190 in step S130 and before forming the intervening layer 66 in step S140.

In step S140, the intervening layer 66 is provided above the interlayer dielectric film 38. Step S140 of providing the intervening layer 66 may include a step of providing the intervening layer 66 containing titanium nitride. Step S140 of providing the intervening layer 66 may include a step of providing the intervening layer 66 including a silicon oxide film.

When step S140 of providing the intervening layer 66 includes the step of providing the intervening layer 66 containing the titanium nitride, the intervening layer 66 may be formed by sputtering titanium nitride above the interlayer dielectric film 38. When step S140 of providing the intervening layer 66 includes the step of providing the intervening layer 66 including the silicon oxide film, the intervening layer 66 may be formed by depositing an LTO film or an HTO film above the interlayer dielectric film 38, or may be formed by depositing a TEOS film above the interlayer dielectric film 38 using Plasma Enhanced CVD.

In step S150, annealing is performed. Through annealing treatment, the plug region 19 may be formed in a region at the bottom of the contact hole into which the impurity ions 190 have been implanted, and in a region where an impurity has diffused.

In step S160, the barrier metal layer 60 is provided above the intervening layer 66. Step S160 of providing the barrier metal layer 60 may include step S162 of providing the first barrier metal portion 61 above the intervening layer 66 and step S164 of providing the second barrier metal portion 62 above the first barrier metal portion 61. Step S162 of providing the first barrier metal portion 61 may include a step of providing the first barrier metal portion 61 containing titanium. For example, step S162 of providing the first barrier metal portion 61 includes a step of sputtering titanium. Step S164 of providing the second barrier metal portion 62 may include a step of providing the second barrier metal portion 62 containing titanium nitride. For example, step S164 of providing the second barrier metal portion 62 includes a step of sputtering titanium nitride.

In step S170, sintering is performed. During a sintering process, at least a part of the titanium may be nitrided to form titanium nitride. That is, step S170 of performing sintering may be a part of step S160 of providing the barrier metal layer 60, and may be a part of step S164 of providing the second barrier metal portion 62. For example, combination of the step of sputtering the titanium and step S170 of performing the sintering may be a part of step S164 of providing the second barrier metal portion 62.

In step S180, the silicide layer 63 is provided above the silicon layer 110, in the contact hole provided in the interlayer dielectric film 38. Step S180 of providing the silicide layer 63 may be a part of step S170 of performing the sintering. That is, the silicide layer 63 may be formed as a result of the material of the barrier metal layer 60, which is deposited at the bottom of the contact hole, reacting with silicon of the silicon layer 110 during the sintering process to form a silicide. At this time, the silicide layer 63 may be formed to a position deeper than the front surface 21. The silicide layer 63 may include a product of a reaction between the barrier metal layer 60 and the silicon layer 110 during the sintering process, may include a product of a reaction between the barrier metal layer 60 and the intervening layer 66 during the sintering process, or may include a product of a reaction between the intervening layer 66 and the silicon layer 110 during the sintering process.

In step S190, the front-surface-side metal layer 53 is provided above the barrier metal layer 60. The process of manufacturing the semiconductor apparatus 100 may include a stage of providing the plug layer 64 before step S180 of providing the front-surface-side metal layer 53. For example, tungsten may be formed by CVD so as to fill the interior of the contact hole, and an unnecessary tungsten film outside the contact hole may be removed by etch-back. The front-surface-side metal layer 53 that has been deposited may be patterned, and the barrier metal layer 60 may also be patterned simultaneously. When the intervening layer 66 is made of an electrically conductive material such as titanium nitride, it is patterned similarly to the front-surface-side metal layer 53 and the barrier metal layer 60, and the intervening layer 66 is not left on the upper surface of the interlayer dielectric film 38 between the respective front-surface-side metal layers 53. When the intervening layer 66 is made of an insulating material such as a silicon oxide film, the intervening layer 66 may not be patterned, and may be left on the upper surface of the interlayer dielectric film 38 between the respective front-surface-side metal layers 53.

The process of manufacturing the semiconductor apparatus 100 in the present example includes step S150 of performing the annealing after step S140 of providing the intervening layer 66 and before step S162 of providing the first barrier metal portion 61, and step S170 of performing the sintering after step S164 of providing the second barrier metal portion 62 and before step S190 of providing the front-surface-side metal layer 53. Step S150 of performing the annealing may be omitted. That is, the process of manufacturing the semiconductor apparatus 100 may include S170 of performing the sintering after step S164 of providing the second barrier metal portion 62 and before the stage of providing the front-surface-side metal layer 53, without performing annealing after step S140 of providing the intervening layer 66 and before step S162 of providing the first barrier metal portion 61. In this case, in step S170 of performing the sintering, the plug region 19 may be formed in the region at the bottom of the contact hole into which the impurity ions 190 have been implanted. In addition, step S150 of performing the annealing may be performed before step S140 of providing the intervening layer 66. In this order, the intervening layer 66 is not overheated even when desired high-temperature annealing is performed to form the plug region 19. In addition, when step S140 of providing the intervening layer 66 involves heating, as a result, the plug region 19 may be formed in the region at the bottom of the contact hole into which the impurity ions 190 have been implanted.

After step S140 of providing the intervening layer 66 and before step S160 of providing the barrier metal layer 60, a step may be provided in which the intervening layer 66 at the bottom of the contact hole is etched to remove or to thin the intervening layer 66. By providing the step of etching the intervening layer 66, the thickness of the intervening layer 66 at the bottom of the contact hole and of the intervening layer 66 above the interlayer dielectric film 38 can be changed finely. This makes it possible to eliminate issues such as: the intervening layer 66 at the bottom of the contact hole being thick, which hinders the formation of the silicide layer 63, or high electrical resistance of the intervening layer 66 itself becoming problematic; or the intervening layer 66 above the interlayer dielectric film 38 being thin, which results in insufficient improvement in adhesion with the barrier metal layer 60. When the intervening layer 66 at a side surface of the contact hole is removed, the resulting contact hole may have the structure shown in FIGS. 5A or 5B .

FIG. 11B shows an example of a process of manufacturing the semiconductor apparatus 100. The manufacturing process in the present example is an example of a manufacturing process corresponding to the flowchart in FIG. 11A.

In step S100, the interlayer dielectric film 38 made of silicate glass is provided above the silicon layer 110. In step S110, the contact hole is provided in the interlayer dielectric film 38; in step S120, the resist 192 is provided; and in step S130, the impurity ions 190 are implanted into the bottom of the contact hole in the opening of the resist 192. When the impurity ions 190 are implanted from above the semiconductor substrate 10, the impurity ions 190 are also implanted into the second insulating layer 384, the upper surface of which is exposed without being covered with the resist 192, and the halogen concentration or the boron concentration in the second insulating layer 384 may increase.

In step S140, the intervening layer 66 is provided above the interlayer dielectric film 38. In the present example, since the contact hole is formed in step S110, the intervening layer 66 is also formed at the bottom and sidewall of the contact hole. In step S150, the annealing is performed. Through annealing treatment, the plug region 19 is formed in the region at the bottom of the contact hole into which the ions have been implanted, and in the region where the impurity has diffused.

In step S160, the barrier metal layer 60 is provided above the intervening layer 66. In the present example, since the contact hole is formed in step S110, the first barrier metal portion 61 and the second barrier metal portion 62 are also formed at the bottom and sidewall of the contact hole.

In step S170, the sintering is performed, and in step S180, the silicide layer 63 is provided above the silicon layer 110, in the contact hole provided in the interlayer dielectric film 38. The intervening layer 66, the first barrier metal portion 61 formed at the bottom of the contact hole contribute to silicidation in step S170 and step S180, and the silicide layer 63 is formed. At this time, the silicide layer 63 may be formed to a position deeper than the front surface 21. It should be noted that, as shown in the examples in FIGS. 4A and 4B , at least a part of the intervening layer 66 may remain without contributing to the silicidation.

In step S190, the front-surface-side metal layer 53 is provided above the barrier metal layer 60. The plug layer 64 may be provided before step S190.

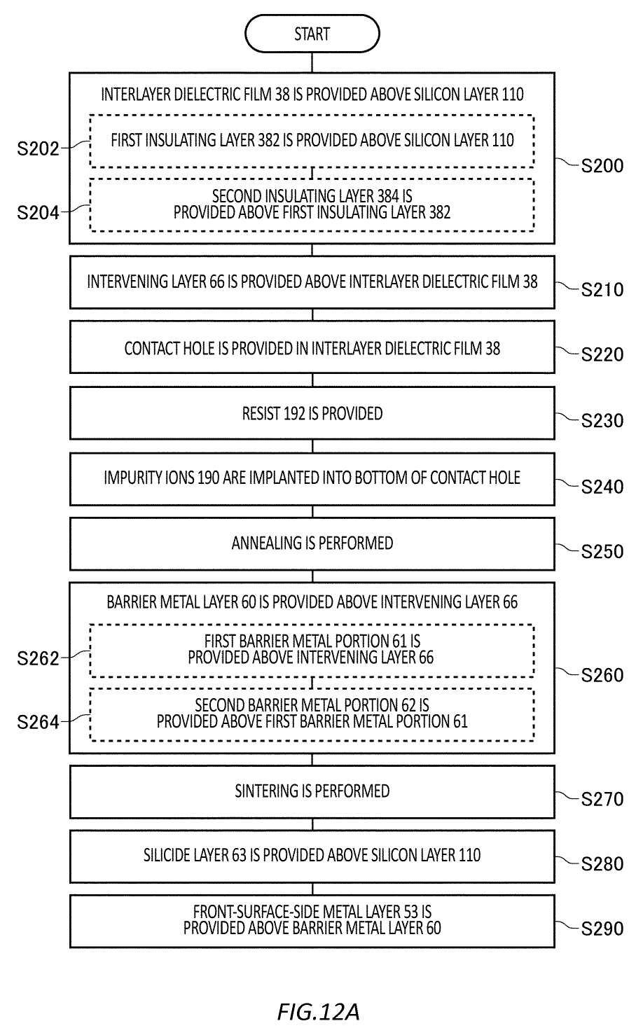

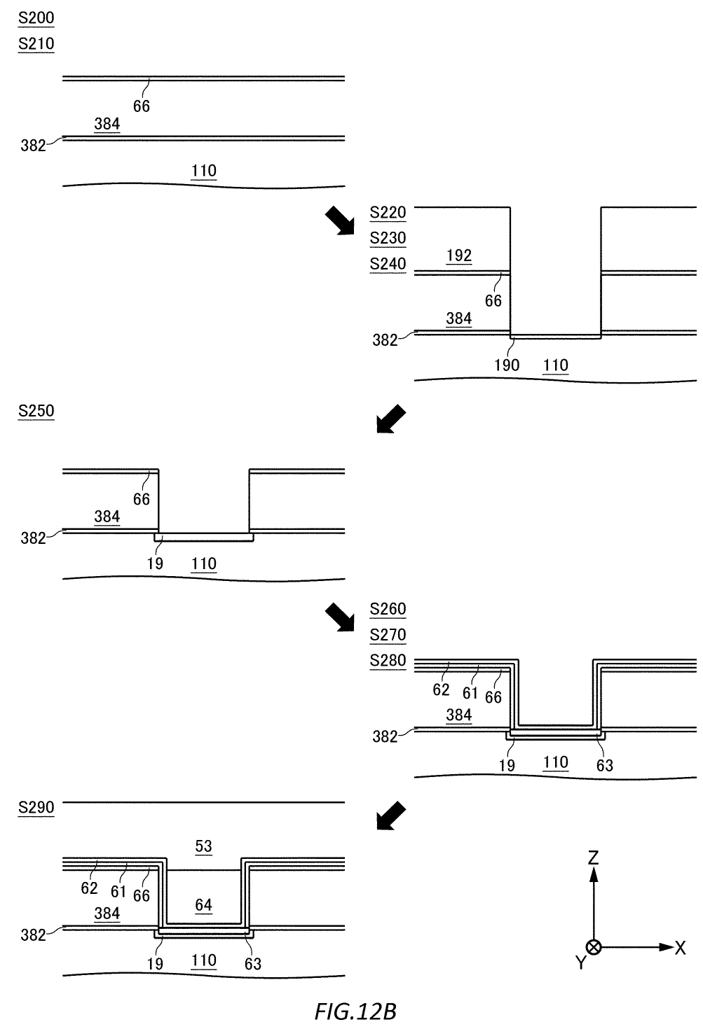

FIG. 12A is a flowchart showing an example of a process of manufacturing the semiconductor apparatus 100. The process of manufacturing the semiconductor apparatus 100 in the present example differs from that in the example shown in FIG. 11A in that the order of a step of providing the intervening layer 66 and a step of providing the contact hole is different. In the present example, differences with the example shown in FIG. 11A will be particularly described, and other configurations may be the same as those in the example shown in FIG. 11A.

In step S200, the interlayer dielectric film 38 made of silicate glass is provided above the silicon layer 110. The details of step S200, step S202, and step S204 may be the same as those of step S100, step S102, and step S104 in FIG. 11A.

In step S210, the intervening layer 66 is provided above the interlayer dielectric film 38. The details of a method for providing the intervening layer 66 may be the same as step S140 in FIG. 11A.

In step S220, a contact hole is provided in the interlayer dielectric film 38. The contact hole may be provided by etching the intervening layer 66 and the interlayer dielectric film 38. In step S220, contact holes such as the contact hole 54, the contact hole 55, the contact hole 56, and the contact hole 58 may be formed in the interlayer dielectric film 38. The process of manufacturing the semiconductor apparatus 100 in the present example may include step S220 of providing the contact hole in the interlayer dielectric film 38 after step S210 of providing the intervening layer 66 and before step S260 of providing the barrier metal layer 60. Therefore, the process of manufacturing the semiconductor apparatus 100 in the present example may be the process of manufacturing the semiconductor apparatus 100 according to FIGS. 5A and 5B .

In step S230, the resist 192 is provided. The resist 192 may cover a part or the entirety of the area above the intervening layer 66. In step S240, the impurity ions 190 are implanted into the bottom of the contact hole in the opening of the resist 192. That is, the process of manufacturing the semiconductor apparatus 100 in the present example may include step S240 of implanting the impurity ions 190 into the bottom of the contact hole after step S220 of providing the contact hole and before step S260 of providing the barrier metal layer 60, and may include step S230 of providing the resist 192 above the intervening layer 66 before step S240 of implanting the impurity ions 190 into the bottom of the contact hole.

By providing the resist 192 before implanting the impurity ions 190, it is possible to prevent the impurity ions 190 from being implanted into the bottom of the contact hole in which the plug region 19 is not provided. At this time, by also covering the intervening layer 66 with the resist 192, it is possible to prevent an increase in the halogen concentration or the boron concentration in the intervening layer 66 and in the interlayer dielectric film 38 below it. It should be noted, however, that step S230 of providing the resist 192 may be omitted. In addition, when the concentration of the implanted impurity ions 190 is low or the like, the resist 192 may not be provided above the intervening layer 66. The resist 192 is removed after the implantation of the impurity ions 190 in step S240.

In step S250, annealing is performed. Through annealing treatment, the plug region 19 may be formed in a region at the bottom of the contact hole into which the impurity ions 190 have been implanted, and in a region where an impurity has diffused. It should be noted, however, that step S250 of performing the annealing may be omitted as described in connection with FIG. 11A. In this case, in step S270 of performing sintering, which will be described later, the plug region 19 may be formed.

In step S260, the barrier metal layer 60 is provided above the intervening layer 66. In step S270, the sintering is performed. In step S280, the silicide layer 63 is provided above the silicon layer 110, in the contact hole provided in the interlayer dielectric film 38.

In step S290, the front-surface-side metal layer 53 is provided above the barrier metal layer 60. The details of step S260 to step S290 may be the same as those of step S160 to step S190 in FIG. 11A.

FIG. 12B shows an example of a process of manufacturing the semiconductor apparatus 100. The manufacturing process in the present example is an example of a manufacturing process corresponding to the flowchart in FIG. 12A.

In step S200, the interlayer dielectric film 38 made of silicate glass is provided above the silicon layer 110, and in step S210, the intervening layer 66 is provided above the interlayer dielectric film 38.

In step S220, the contact hole is provided in the interlayer dielectric film 38; in step S230, the resist 192 is provided; and in step S240, the impurity ions 190 are implanted into the bottom of the contact hole in the opening of the resist 192. The resist 192 may also cover the area above the intervening layer 66. In the process of manufacturing the semiconductor apparatus 100 in the present example, since the contact hole is provided after the intervening layer 66 is provided, the intervening layer 66 is not formed at the bottom and sidewall of the contact hole. In addition, by providing the resist 192 before implanting the impurity ions 190, the plug region 19 can be selectively formed at the bottom of the contact hole, and by also covering the area above the intervening layer 66 with the resist 192, it is possible to prevent the increase in the halogen concentration or the boron concentration in the intervening layer 66 and in the interlayer dielectric film 38 below it.

In step S250, the annealing is performed. Through annealing treatment, the plug region 19 is formed in the region at the bottom of the contact hole into which the ions have been implanted, and in the region where the impurity has diffused.

In step S260, the barrier metal layer 60 is provided above the intervening layer 66. In the present example, since the contact hole is formed in step S220, the first barrier metal portion 61 and the second barrier metal portion 62 are also formed at the bottom and sidewall of the contact hole.

In step S270, the sintering is performed, and in step S280, the silicide layer 63 is provided above the silicon layer 110, in the contact hole provided in the interlayer dielectric film 38. The first barrier metal portion 61 formed at the bottom of the contact hole contributes to silicidation in step S270 and step S280, and the silicide layer 63 is formed. At this time, the silicide layer 63 may be formed to a position deeper than the front surface 21.

In step S290, the front-surface-side metal layer 53 is provided above the barrier metal layer 60. The plug layer 64 may be provided before step S280.

While the present invention has been described by way of the embodiments, the technical scope of the present invention is not limited to the above-described embodiments. It is apparent to persons skilled in the art that various modifications or improvements can be made to the above described embodiments. It is also apparent from description of the claims that the embodiments to which such modifications or improvements are made may be included in the technical scope of the present invention.

It should be noted that each process of the operations, procedures, steps, stages, and the like performed by the apparatus, system, program, and method shown in the claims, specification, or drawings can be executed in any order as long as the order is not indicated by “prior to”, “before”, or the like and as long as the output from a previous process is not used in a later process. Even if the operation flow is described using phrases such as "first" or "next" for the sake of convenience in the claims, specification, or drawings, it does not necessarily mean that the process must be performed in this order.

### Item 1

A semiconductor apparatus comprising:
a silicon layer;
an interlayer dielectric film made of silicate glass, which has a contact hole and is provided above the silicon layer;
an intervening layer provided above the interlayer dielectric film;
a barrier metal layer provided above the intervening layer;
a front-surface-side metal layer provided above the barrier metal layer; and
a silicide layer provided above the silicon layer in the contact hole.

### Item 2

The semiconductor apparatus according to item 1, wherein
a thickness of the intervening layer is smaller than a thickness of the interlayer dielectric film.

### Item 3

The semiconductor apparatus according to item 1, wherein
a thickness of the intervening layer above the interlayer dielectric film is 3 nm or more and 20 nm or less.

### Item 4

The semiconductor apparatus according to item 1, wherein
the barrier metal layer is in contact with the silicide layer.

### Item 5

The semiconductor apparatus according to any one of items 1 to 4, wherein
a fluorine concentration in the intervening layer is lower than a fluorine concentration at an upper surface of the interlayer dielectric film.

### Item 6

The semiconductor apparatus according to any one of items 1 to 4, wherein the interlayer dielectric film includes:
a first insulating layer provided above the silicon layer; and
a second insulating layer provided above the first insulating layer and having a higher fluorine concentration than the first insulating layer.

### Item 7

The semiconductor apparatus according to item 6, wherein
the intervening layer is in contact with the second insulating layer.

### Item 8

The semiconductor apparatus according to any one of items 1 to 4, wherein the barrier metal layer includes:
a first barrier metal portion provided above the intervening layer; and
a second barrier metal portion provided above the first barrier metal portion.

### Item 9

The semiconductor apparatus according to item 8, wherein
the first barrier metal portion and the second barrier metal portion are provided above the interlayer dielectric film and at a sidewall of the contact hole, and
the first barrier metal portion is in contact with the sidewall of the contact hole.

### Item 10

The semiconductor apparatus according to item 8, wherein
the intervening layer, the first barrier metal portion, and the second barrier metal portion are provided above the interlayer dielectric film and at a sidewall of the contact hole.

### Item 11

The semiconductor apparatus according to item 8, wherein
the intervening layer contains titanium nitride.

### Item 12

The semiconductor apparatus according to item 11, wherein
the first barrier metal portion contains titanium, and
the second barrier metal portion contains titanium nitride.

### Item 13

The semiconductor apparatus according to item 12, wherein
the second barrier metal portion contains titanium nitride having a higher density than the titanium nitride contained in the intervening layer.

### Item 14

The semiconductor apparatus according to item 8, wherein
the intervening layer includes a silicon oxide film.

### Item 15

The semiconductor apparatus according to item 14, wherein
the first barrier metal portion contains titanium, and
the second barrier metal portion contains titanium nitride.

### Item 16

A semiconductor apparatus comprising:
a base layer;
an interlayer dielectric film including a contact hole and provided above the base layer;
an intervening layer provided above the interlayer dielectric film;
a barrier metal layer provided above the intervening layer;
a front-surface-side metal layer provided above the barrier metal layer; and
an alloy layer provided above the base layer in the contact hole.

### Item 17

A method for manufacturing a semiconductor apparatus, the method comprising:
providing an interlayer dielectric film made of silicate glass above a silicon layer;
providing an intervening layer above the interlayer dielectric film;
providing a barrier metal layer above the intervening layer;
providing a silicide layer above the silicon layer in a contact hole provided in the interlayer dielectric film; and
providing a front-surface-side metal layer above the barrier metal layer.

### Item 18

The method for manufacturing the semiconductor apparatus according to item 17, the method comprising
providing the contact hole in the interlayer dielectric film after the providing the interlayer dielectric film and before the providing the intervening layer.

### Item 19

The method for manufacturing the semiconductor apparatus according to item 18, the method comprising
implanting halide ions into the bottom of the contact hole after the providing the contact hole and before the providing the intervening layer.

### Item 20

The method for manufacturing the semiconductor apparatus according to item 17, the method comprising
providing the contact hole in the interlayer dielectric film after the providing the intervening layer and before the providing the barrier metal layer.

### Item 21

The method for manufacturing the semiconductor apparatus according to item 20, the method comprising
implanting halide ions into the bottom of the contact hole after the providing the contact hole and before the providing the barrier metal layer.

### Item 22

The method for manufacturing the semiconductor apparatus according to item 21, the method comprising
providing a resist above the intervening layer before the implanting the halide ions into the bottom of the contact hole.

### Item 23

The method for manufacturing the semiconductor apparatus according to any one of items 17 to 22, wherein
the providing the interlayer dielectric film includes:
providing a first insulating layer above the silicon layer; and
providing a second insulating layer above the first insulating layer.

### Item 24

The method for manufacturing the semiconductor apparatus according to any one of items 17 to 22, wherein the providing the barrier metal layer includes:
providing a first barrier metal portion above the intervening layer; and
providing a second barrier metal portion above the first barrier metal portion.

### Item 25

The method for manufacturing the semiconductor apparatus according to item 24, the method comprising:
performing annealing after the providing the intervening layer and before the providing the first barrier metal portion; and
performing sintering after the providing the second barrier metal portion and before the providing the front-surface-side metal layer.

### Item 26

The method for manufacturing the semiconductor apparatus according to item 24, the method comprising
performing sintering after the providing the second barrier metal portion and before the providing the front-surface-side metal layer, without performing annealing after the providing the intervening layer and before the providing the first barrier metal portion.

### Item 27

The method for manufacturing the semiconductor apparatus according to item 24, wherein
the providing the intervening layer includes providing the intervening layer containing titanium nitride.

### Item 28

The method for manufacturing the semiconductor apparatus according to item 27, wherein
the providing the first barrier metal portion includes providing the first barrier metal portion containing titanium, and
the providing the second barrier metal portion includes providing the second barrier metal portion containing titanium nitride.

### Item 29

The method for manufacturing the semiconductor apparatus according to item 24, wherein
the providing the intervening layer includes providing the intervening layer including a silicon oxide film.

### Item 30

The method for manufacturing the semiconductor apparatus according to item 29, wherein
the providing the first barrier metal portion includes providing the first barrier metal portion containing titanium, and
the providing the second barrier metal portion includes providing the second barrier metal portion containing titanium nitride.

### Item 31

A method for manufacturing a semiconductor apparatus, the method comprising:
providing an interlayer dielectric film above a base layer;
providing an intervening layer above the interlayer dielectric film;
providing a barrier metal layer above the intervening layer;
providing an alloy layer above the base layer in a contact hole provided in the interlayer dielectric film; and
providing a front-surface-side metal layer above the barrier metal layer.

### EXPLANATION OF REFERENCES

10: semiconductor substrate, 12: emitter region, 14: base region, 15: contact region, 16: accumulation region, 17: well region, 18: drift region, 19: plug region, 20: buffer region, 21: front surface, 22: collector region, 23: back surface, 24: collector electrode, 25: connection section, 26: insulating layer, 30: dummy trench portion, 31: extending portion, 32: dummy dielectric film, 33: connection portion, 34: dummy conductive portion, 38: interlayer dielectric film, 40: gate trench portion, 41: extending portion, 42: gate dielectric film, 43: connection portion, 44: gate conductive portion, 50: gate metal layer, 52: emitter electrode, 53: front-surface-side metal layer, 54: contact hole, 55: contact hole, 56: contact hole, 58: contact hole, 60: barrier metal layer, 61: first barrier metal portion, 62: second barrier metal portion, 63: silicide layer, 64: plug layer, 66: intervening layer, 68: covering layer, 70: transistor portion, 71: mesa portion, 80: diode portion, 81: mesa portion, 82: cathode region, 85: extension region, 90: boundary portion, 91: mesa portion, 100: semiconductor apparatus, 102: end side, 110: silicon layer, 112: gate pad, 114: sensing electrode, 115: current sensing unit, 116: anode pad, 117: anode wiring, 118: cathode pad, 119: cathode wiring, 120: active portion, 130: outer circumferential gate wiring, 131: inter-active-portion gate wiring, 140: edge termination structure portion, 151: back-surface-side lifetime control region, 152: front-surface-side lifetime control region, 164: opening region, 180: temperature sensing unit, 181: cathode region, 182: anode region, 184: dielectric film, 186: cathode electrode, 187: anode electrode, 190: impurity ion, 192: resist, 382: first insulating layer, 384: second insulating layer.

What is claimed is:

1. A semiconductor apparatus comprising:
a silicon layer;
an interlayer dielectric film made of silicate glass, which includes a contact hole and is provided above the silicon layer;
an intervening layer provided above the interlayer dielectric film;
a barrier metal layer provided above the intervening layer;
a front-surface-side metal layer provided above the barrier metal layer; and
a silicide layer provided above the silicon layer in the contact hole.

2. The semiconductor apparatus according to claim 1, wherein
a thickness of the intervening layer is smaller than a thickness of the interlayer dielectric film.

3. The semiconductor apparatus according to claim 1, wherein
a thickness of the intervening layer above the interlayer dielectric film is 3 nm or more and 20 nm or less.

4. The semiconductor apparatus according to claim 1, wherein
the barrier metal layer is in contact with the silicide layer.

5. The semiconductor apparatus according to claim 1, wherein
a fluorine concentration in the intervening layer is lower than a fluorine concentration at an upper surface of the interlayer dielectric film.

6. The semiconductor apparatus according to claim 2, wherein
a fluorine concentration in the intervening layer is lower than a fluorine concentration at an upper surface of the interlayer dielectric film.

7. The semiconductor apparatus according to claim 1, wherein the interlayer dielectric film includes:
a first insulating layer provided above the silicon layer; and
a second insulating layer provided above the first insulating layer and having a higher fluorine concentration than the first insulating layer.

8. The semiconductor apparatus according to claim 7, wherein
the intervening layer is in contact with the second insulating layer.

9. The semiconductor apparatus according to claim 2, wherein the interlayer dielectric film includes:
a first insulating layer provided above the silicon layer; and
a second insulating layer provided above the first insulating layer and having a higher fluorine concentration than the first insulating layer.

10. The semiconductor apparatus according to claim 9, wherein
the intervening layer is in contact with the second insulating layer.

11. The semiconductor apparatus according to claim 1, wherein the barrier metal layer includes:
a first barrier metal portion provided above the intervening layer; and
a second barrier metal portion provided above the first barrier metal portion.

12. The semiconductor apparatus according to claim 11, wherein
the first barrier metal portion and the second barrier metal portion are provided above the interlayer dielectric film and at a sidewall of the contact hole, and
the first barrier metal portion is in contact with the sidewall of the contact hole.

13. The semiconductor apparatus according to claim 11, wherein
the intervening layer, the first barrier metal portion, and the second barrier metal portion are provided above the interlayer dielectric film and at a sidewall of the contact hole.

14. The semiconductor apparatus according to claim 11, wherein
the intervening layer contains titanium nitride.

15. The semiconductor apparatus according to claim 14, wherein
the first barrier metal portion contains titanium, and
the second barrier metal portion contains titanium nitride.

16. The semiconductor apparatus according to claim 15, wherein
the second barrier metal portion contains titanium nitride having a higher density than the titanium nitride contained in the intervening layer.

17. The semiconductor apparatus according to claim 11, wherein
the intervening layer includes a silicon oxide film.

18. The semiconductor apparatus according to claim 17, wherein
the first barrier metal portion contains titanium, and
the second barrier metal portion contains titanium nitride.

19. The semiconductor apparatus according to claim 2, wherein the barrier metal layer includes:
a first barrier metal portion provided above the intervening layer; and
a second barrier metal portion provided above the first barrier metal portion.

20. A semiconductor apparatus comprising:
a base layer;
an interlayer dielectric film including a contact hole and provided above the base layer;
an intervening layer provided above the interlayer dielectric film;
a barrier metal layer provided above the intervening layer;
a front-surface-side metal layer provided above the barrier metal layer; and
an alloy layer provided above the base layer in the contact hole.
